(19) United States
(12) Patent Application Publication
(10) Pub. No.: US 2021/0117418 A1
(43) Pub. Date: Apr. 22, 2021

(54) TIME-AWARE GENERAL-PURPOSE INPUT OUTPUT FOR INDUSTRIAL CONTROL SYSTEMS

(71) Applicants: Vikram Dadwal, Chandler, AZ (US); Christopher Shawn Michael Hall, Portland, OR (US)

(72) Inventors: Vikram Dadwal, Chandler, AZ (US); Christopher Shawn Michael Hall, Portland, OR (US)

(21) Appl. No.: 17/133,293

(22) Filed: Dec. 23, 2020

(51) Int. Cl. G06F 16/2458; G06N 7/02; G06N 20/00; G05B 19/402

(52) U.S. Cl. CPC G06F 16/2465; G06N 7/02; G06F 16/2468; H03M 7/30; G05B 19/402; G05B 2219/39132; G05B 2219/45091; G06N 20/00

(57) ABSTRACT

Various systems and methods for implementing time-aware general-purpose input output (TGPIO) for industrial control systems are described herein. A system includes edge detector circuitry to: detect rising or falling edges in an input signal; and store the rising or falling edges in a buffer along with a corresponding timestamp of the respective edge; and pattern match circuitry to: analyze the rising or falling edges in the buffer to identify a pattern of edges that matches a search pattern; and store timestamps corresponding to the pattern of edges in an event queue, the event queue used to notify a user application of the existence of the pattern of edges in the input signal.

### TECHNICAL FIELD

Embodiments described herein generally relate to digital industrial control hardware systems and in particular, to a system that provides time-aware general-purpose input output (TGPIO) for industrial control systems.

### BACKGROUND

Edge computing, at a general level, refers to the transition of compute and storage resources closer to endpoint devices (e.g., consumer computing devices, user equipment, etc.) in order to optimize total cost of ownership, reduce application latency, improve service capabilities, and improve compliance with security or data privacy requirements. Edge computing may, in some scenarios, provide a cloud-like distributed service that offers orchestration and management for applications among many types of storage and compute resources. As a result, some implementations of edge computing have been referred to as the “edge cloud” or the “fog”, as powerful computing resources previously available only in large remote data centers are moved closer to endpoints and made available for use by consumers at the “edge” of the network.

Edge computing use cases in mobile network settings have been developed for integration with multi-access edge computing (MEC) approaches, also known as “mobile edge computing.” MEC approaches are designed to allow application developers and content providers to access computing capabilities and an information technology (IT) service environment in dynamic mobile network settings at the edge of the network. Limited standards have been developed by the European Telecommunications Standards Institute (ETSI) industry specification group (ISG) in an attempt to define common interfaces for operation of MEC systems, platforms, hosts, services, and applications.

Edge computing, MEC, and related technologies attempt to provide reduced latency, increased responsiveness, and more available computing power than offered in traditional cloud network services and wide area network connections. However, the integration of mobility and dynamically launched services to some mobile use and device processing use cases has led to limitations and concerns with orchestration, functional coordination, and resource management, especially in complex mobility settings where many participants (devices, hosts, tenants, service providers, operators) are involved. In a similar manner, Internet of Things (IoT) networks and devices are designed to offer a distributed compute arrangement, from a variety of endpoints. IoT devices are physical or virtualized objects that may communicate on a network, and may include sensors, actuators, and other input/output components, which may be used to collect data or perform actions in a real world environment. For example, IoT devices may include low-powered endpoint devices that are embedded or attached to everyday things, such as buildings, vehicles, packages, etc., to provide an additional level of artificial sensory perception of those things. Recently, IoT devices have become more popular and thus applications using these devices have proliferated.

The deployment of various Edge, Fog, MEC, and IoT networks, devices, and services have introduced a number of advanced use cases and scenarios occurring at and towards the edge of the network. However, these advanced use cases have also introduced a number of corresponding technical challenges relating to security, processing and network resources, service availability and efficiency, among many other issues, especially as more types of computing systems and configurations are deployed. One such challenge is in relation to security and trust, and the operational states of software programs and data, as represented in memory (e.g., DRAM memory), cache memory (e.g., in a cache), or registers (e.g., CPU, or GPU).

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings in which:

FIG. 1 illustrates an overview of an edge cloud configuration for edge computing;

FIG. 2 illustrates operational layers among endpoints, an edge cloud, and cloud computing environments;

FIG. 3 illustrates an example approach for networking and services in an edge computing system;

FIG. 4A provides an overview of example components for compute deployed at a compute node in an edge computing system;

FIG. 4B provides a further overview of example components within a computing device in an edge computing system;

FIG. 5 is a block diagram illustrating a time-aware general-purpose input output (TGPIO) system, according to an embodiment;

FIG. 6 is a block diagram illustrating an architecture for implementing a time-aware general-purpose input output (TGPIO) system, according to an embodiment;

FIG. 7 is a diagram illustrating a series of pulses in a signal, according to an embodiment;

FIG. 8 is a flowchart illustrating a TGPIO filter process, according to an embodiment;

FIG. 9 is a flowchart illustrating a method for searching TGPIO signals for patterns, according to an embodiment;

FIG. 10 is a block diagram illustrating a time-aware general-purpose input output (TGPIO) system, according to an embodiment;

FIG. 11 is a flowchart illustrating a process to manage a TGPIO queue, according to an embodiment;

FIG. 12 shows the policy of preserving the Nth oldest entries in a queue;

FIG. 13 is a diagram illustrating intragroup compression, according to an embodiment;

FIG. 14 is a flowchart illustrating a method for timestamp queue management, according to an embodiment:

FIG. 15 is a flowchart illustrating a method for time-aware general purpose input/output signal compression, according to an embodiment; and

FIG. 16 is a block diagram illustrating an example machine upon which any one or more of the techniques (e.g., methodologies) discussed herein may perform, according to an example embodiment.

### DETAILED DESCRIPTION

Systems and methods described herein provide a system that provides time-aware general-purpose input output (TGPIO) for industrial control systems. In various examples, the systems and methods described herein improve event handling in a TGPIO system.

A GPIO is a digital signal pin on an electronic circuit board whose behavior, including whether it acts as input or output, is controllable by the user at run time. GPIO signals are used by software to control or communicate with components external to the CPU. Standard GPIO (SGPIO) signaling logic does not have the capability to capture time and the precision of signal timing is limited by that of the triggering software event. Each SGPIO event must also be individually triggered by software requiring CPU intervention and may result in jitter.

Modern products include Time-Aware GPIO (TGPIO) hardware that addresses these limitations by adding additional logic that samples input events and captures timestamps with respect to the system clock with sub-microsecond precision. Some architectures use the Always Running Timer (ART) to synchronize events across the system including TOPIO.

One application enhanced by TGPIO is manufacturing control. Manufacturing processes require a series of steps to be performed in a precisely timed and ordered manner. TGPIO signaling can be uses for precise (sub-microsecond) control. These processes can be synchronized across several machines using TSN time synchronization. The local TSN clock is also related to the ART and synchronized with TGPIO using hardware logic.

Time-aware GPIO is used to timestamp captured input or generate synchronized output signals on the GPIO pins. In particular, the TGPIO interface captures input events (rising and falling edges) and timestamps them using ART, or a local device clock. Each of these events generate a notification that must be processed by software. This capability is achieved through use of a TOPIO queue that captures these events. When input is captured, software reads the events from the queue as it is being filled by the TGPIO device. However, current systems do not have a mechanism to handle queue overflows. Instead, queue events are dropped. This provides poor quality of service to applications that are monitoring for events.

For many applications dropping events can be catastrophic. One example application is in a vehicle manufacturing facility using a robotic arm controller that requires precisely timestamped tool movements and/or part positions, such as a robot arm performing welds or inserting bolts or screws. If events are missed, then faulty products or breakdowns in the entire system may occur.

The systems and methods described here provide an improved queue management that reduces CPU overhead and queue overflow for TGPIO processing by prioritizing user-specified input events when compressing the event queue. This mechanism allows TGPIO hardware to sample higher speed signals by intelligently offloading TGPIO event processing to hardware. Consequently, the mechanism provides higher throughput for applications running on the same platform.

Additionally, the systems and methods described here provide an improved filtering technique that is able to use complex time-aware GPIO edge patterns and filter and report only user-specified timestamps based on these patterns. This reduces CPU load needed to process input. The application supplies a search pattern as input to the hardware filter, and the hardware filter uses the search pattern to find matches in the GPIO input. The search pattern may be in the form of a regular expression, fuzzy logic rules, or a finite state machine, in various embodiments.

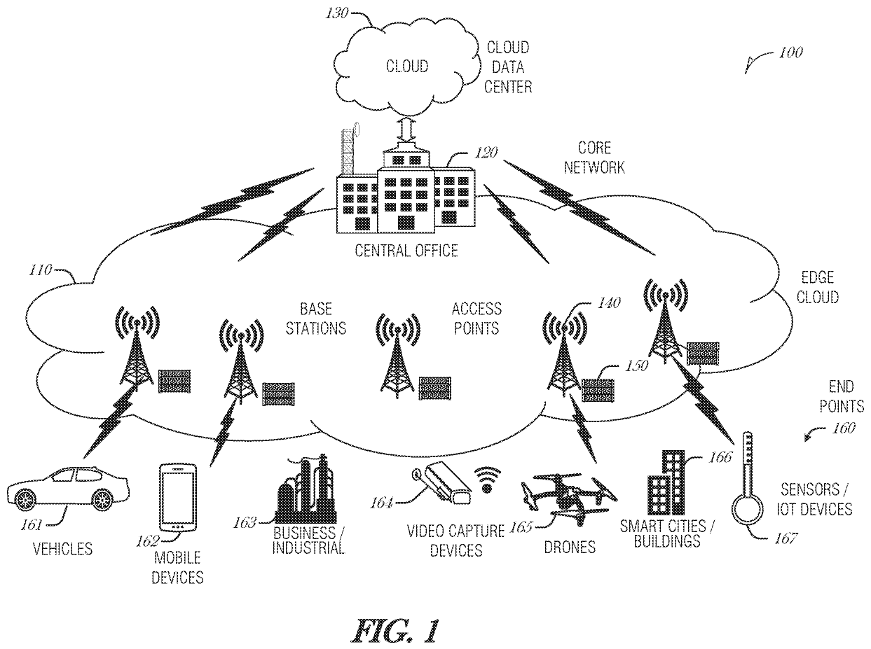

FIG. 1 is a block diagram 100 showing an overview of a configuration for edge computing, which includes a layer of processing referred to in many of the following examples as an “edge cloud”. As shown, the edge cloud 110 is co-located at an edge location, such as an access point or base station 140, a local processing hub 150, or a central office 120, and thus may include multiple entities, devices, and equipment instances. The edge cloud 110 is located much closer to the endpoint (consumer and producer) data sources 160 (e.g., autonomous vehicles 161, user equipment 162, business and industrial equipment 163, video capture devices 164, drones 165, smart cities and building devices 166, sensors and IoT devices 167, etc.) than the cloud data center 130. Compute, memory, and storage resources which are offered at the edges in the edge cloud 110 are critical to providing ultra-low latency response times for services and functions used by the endpoint data sources 160 as well as reduce network backhaul traffic from the edge cloud 110 toward cloud data center 130 thus improving energy consumption and overall network usages among other benefits.

Compute, memory, and storage are scarce resources, and generally decrease depending on the edge location (e.g., fewer processing resources being available at consumer endpoint devices, than at a base station, than at a central office). However, the closer that the edge location is to the endpoint (e.g., user equipment (UE)), the more that space and power is often constrained. Thus, edge computing attempts to reduce the amount of resources needed for network services, through the distribution of more resources which are located closer both geographically and in network access time. In this manner, edge computing attempts to bring the compute resources to the workload data where appropriate, or, bring the workload data to the compute resources.

The following describes aspects of an edge cloud architecture that covers multiple potential deployments and addresses restrictions that some network operators or service providers may have in their own infrastructures. These include, variation of configurations based on the edge location (because edges at a base station level, for instance, may have more constrained performance and capabilities in a multi-tenant scenario); configurations based on the type of compute, memory, storage, fabric, acceleration, or like resources available to edge locations, tiers of locations, or groups of locations; the service, security, and management and orchestration capabilities; and related objectives to achieve usability and performance of end services. These deployments may accomplish processing in network layers that may be considered as “near edge”, “close edge”, “local edge”, “middle edge”, or “far edge” layers, depending on latency, distance, and timing characteristics.

Edge computing is a developing paradigm where computing is performed at or closer to the “edge” of a network, typically through the use of a compute platform (e.g., x86 or ARM compute hardware architecture) implemented at base stations, gateways, network routers, or other devices which are much closer to endpoint devices producing and consuming the data. For example, edge gateway servers may be equipped with pools of memory and storage resources to perform computation in real-time for low latency use-cases (e.g., autonomous driving or video surveillance) for connected client devices. Or as an example, base stations may be augmented with compute and acceleration resources to directly process service workloads for connected user equipment, without further communicating data via backhaul networks. Or as another example, central office network management hardware may be replaced with standardized compute hardware that performs virtualized network functions and offers compute resources for the execution of services and consumer functions for connected devices. Within edge computing networks, there may be scenarios in services which the compute resource will be “moved” to the data, as well as scenarios in which the data will be “moved” to the compute resource. Or as an example, base station compute, acceleration and network resources can provide services in order to scale to workload demands on an as needed basis by activating dormant capacity (subscription, capacity on demand) in order to manage corner cases, emergencies or to provide longevity for deployed resources over a significantly longer implemented lifecycle.

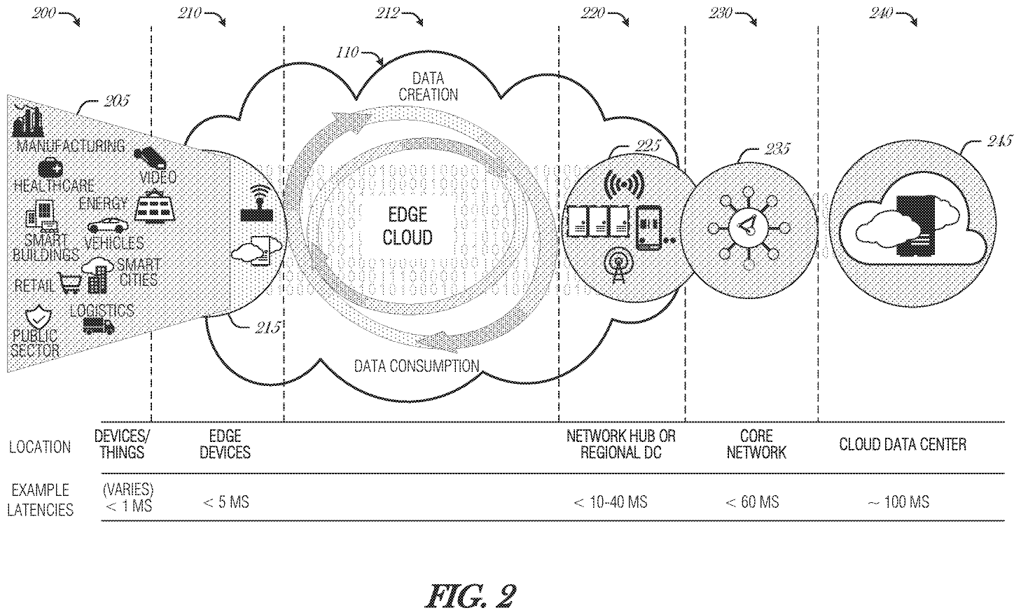

FIG. 2 illustrates operational layers among endpoints, an edge cloud, and cloud computing environments. Specifically, FIG. 2 depicts examples of computational use cases 205, utilizing the edge cloud 110 among multiple illustrative layers of network computing. The layers begin at an endpoint (devices and things) layer 200, which accesses the edge cloud 110 to conduct data creation, analysis, and data consumption activities. The edge cloud 110 may span multiple network layers, such as an edge devices layer 210 having gateways, on-premise servers, or network equipment (nodes 215) located in physically proximate edge systems; a network access layer 220, encompassing base stations, radio processing units, network hubs, regional data centers (DC), or local network equipment (equipment 225); and any equipment, devices, or nodes located therebetween (in layer 212, not illustrated in detail). The network communications within the edge cloud 110 and among the various layers may occur via any number of wired or wireless mediums, including via connectivity architectures and technologies not depicted.

Examples of latency, resulting from network communication distance and processing time constraints, may range from less than a millisecond (ms) when among the endpoint layer 200, under 5 ms at the edge devices layer 210, to even between 10 to 40 ms when communicating with nodes at the network access layer 220. Beyond the edge cloud 110 are core network 230 and cloud data center 240 layers, each with increasing latency (e.g., between 50-60 ms at the core network layer 230, to 100 or more ms at the cloud data center layer). As a result, operations at a core network data center 235 or a cloud data center 245, with latencies of at least 50 to 100 ms or more, will not be able to accomplish many time-critical functions of the use cases 205. Each of these latency values are provided for purposes of illustration and contrast; it will be understood that the use of other access network mediums and technologies may further reduce the latencies. In some examples, respective portions of the network may be categorized as “close edge”, “local edge”, “near edge”, “middle edge”, or “far edge” layers, relative to a network source and destination. For instance, from the perspective of the core network data center 235 or a cloud data center 245, a central office or content data network may be considered as being located within a “near edge” layer (“near” to the cloud, having high latency values when communicating with the devices and endpoints of the use cases 205), whereas an access point, base station, on-premise server, or network gateway may be considered as located within a “far edge” layer (“far” from the cloud, having low latency values when communicating with the devices and endpoints of the use cases 205). It will be understood that other categorizations of a particular network layer as constituting a “close”, “local”, “near”, “middle”, or “far” edge may be based on latency, distance, number of network hops, or other measurable characteristics, as measured from a source in any of the network layers 200-240.

The various use cases 205 may access resources under usage pressure from incoming streams, due to multiple services utilizing the edge cloud. To achieve results with low latency, the services executed within the edge cloud 110 balance varying requirements in terms of: (a) Priority (throughput or latency) and Quality of Service (QoS) (e.g., traffic for an autonomous car may have higher priority than a temperature sensor in terms of response time requirement; or, a performance sensitivity/bottleneck may exist at a compute/accelerator, memory, storage, or network resource, depending on the application); (b) Reliability and Resiliency (e.g., some input streams need to be acted upon and the traffic routed with mission-critical reliability, where as some other input streams may be tolerate an occasional failure, depending on the application); and (c) Physical constraints (e.g., power, cooling and form-factor).

The end-to-end service view for these use cases involves the concept of a service-flow and is associated with a transaction. The transaction details the overall service requirement for the entity consuming the service, as well as the associated services for the resources, workloads, workflows, and business functional and business level requirements. The services executed with the “terms” described may be managed at each layer in a way to assure real time, and runtime contractual compliance for the transaction during the lifecycle of the service. When a component in the transaction is missing its agreed to SLA, the system as a whole (components in the transaction) may provide the ability to (1) understand the impact of the SLA violation, and (2) augment other components in the system to resume overall transaction SLA, and (3) implement steps to remediate.

Thus, with these variations and service features in mind, edge computing within the edge cloud 110 may provide the ability to serve and respond to multiple applications of the use cases 205 (e.g., object tracking, video surveillance, connected cars, etc.) in real-time or near real-time, and meet ultra-low latency requirements for these multiple applications. These advantages enable a whole new class of applications (Virtual Network Functions (VNFs), Function as a Service (FaaS), Edge as a Service (EaaS), standard processes, etc.), which cannot leverage conventional cloud computing due to latency or other limitations.

However, with the advantages of edge computing comes the following caveats. The devices located at the edge are often resource constrained and therefore there is pressure on usage of edge resources. Typically, this is addressed through the pooling of memory and storage resources for use by multiple users (tenants) and devices. The edge may be power and cooling constrained and therefore the power usage needs to be accounted for by the applications that are consuming the most power. There may be inherent power-performance tradeoffs in these pooled memory resources, as many of them are likely to use emerging memory technologies, where more power requires greater memory bandwidth. Likewise, improved security of hardware and root of trust trusted functions are also required, because edge locations may be unmanned and may even need permissioned access (e.g., when housed in a third-party location). Such issues are magnified in the edge cloud 110 in a multi-tenant, multi-owner, or multi-access setting, where services and applications are requested by many users, especially as network usage dynamically fluctuates and the composition of the multiple stakeholders, use cases, and services changes.

At a more generic level, an edge computing system may be described to encompass any number of deployments at the previously discussed layers operating in the edge cloud 110 (network layers 200-240), which provide coordination from client and distributed computing devices. One or more edge gateway nodes, one or more edge aggregation nodes, and one or more core data centers may be distributed across layers of the network to provide an implementation of the edge computing system by or on behalf of a telecommunication service provider (“telco”, or “TSP”), internet-of-things service provider, cloud service provider (CSP), enterprise entity, or any other number of entities. Various implementations and configurations of the edge computing system may be provided dynamically, such as when orchestrated to meet service objectives.

Consistent with the examples provided herein, a client compute node may be embodied as any type of endpoint component, device, appliance, or other thing capable of communicating as a producer or consumer of data. Further, the label “node” or “device” as used in the edge computing system does not necessarily mean that such node or device operates in a client or agent/minion/follower role; rather, any of the nodes or devices in the edge computing system refer to individual entities, nodes, or subsystems which include discrete or connected hardware or software configurations to facilitate or use the edge cloud 110.

As such, the edge cloud 110 is formed from network components and functional features operated by and within edge gateway nodes, edge aggregation nodes, or other edge compute nodes among network layers 210-230. The edge cloud 110 thus may be embodied as any type of network that provides edge computing and/or storage resources which are proximately located to radio access network (RAN) capable endpoint devices (e.g., mobile computing devices, IoT devices, smart devices, etc.), which are discussed herein. In other words, the edge cloud 110 may be envisioned as an “edge” which connects the endpoint devices and traditional network access points that serve as an ingress point into service provider core networks, including mobile carrier networks (e.g., Global System for Mobile Communications (GSM) networks, Long-Term Evolution (LTE) networks, 5G/6G networks, etc.), while also providing storage and/or compute capabilities. Other types and forms of network access (e.g., Wi-Fi, long-range wireless, wired networks including optical networks) may also be utilized in place of or in combination with such 3GPP carrier networks.

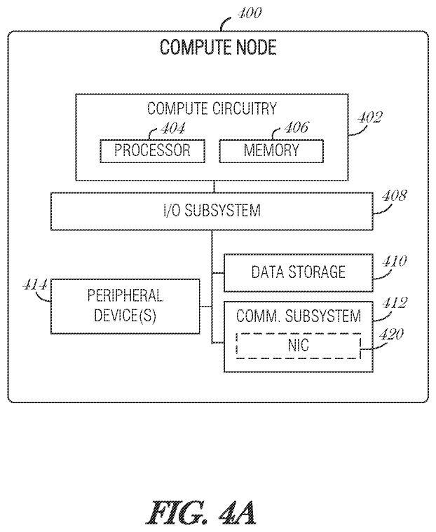

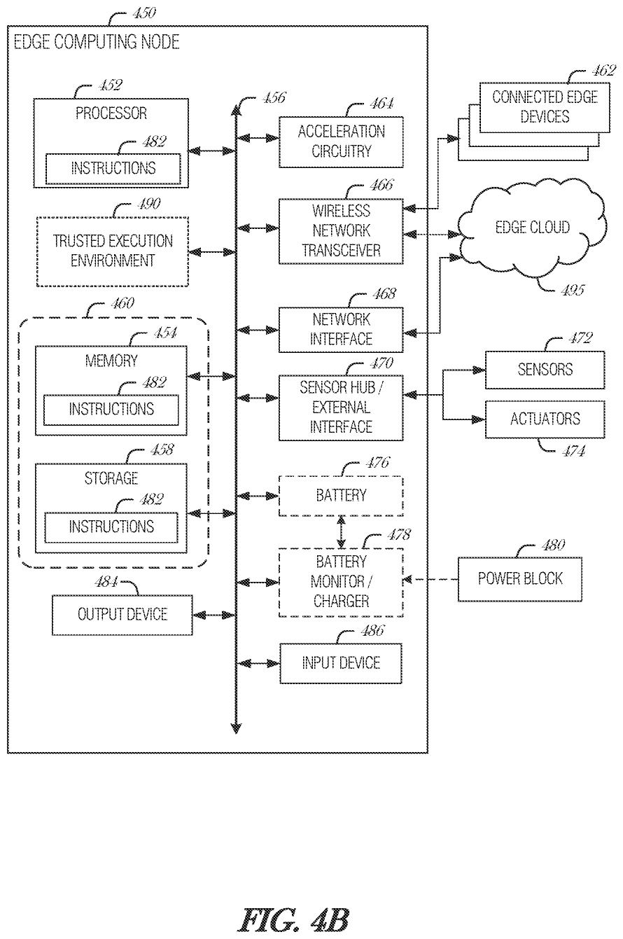

The network components of the edge cloud 110 may be servers, multi-tenant servers, appliance computing devices, and/or any other type of computing devices. For example, the edge cloud 110 may include an appliance computing device that is a self-contained electronic device including a housing, a chassis, a case or a shell. In some circumstances, the housing may be dimensioned for portability such that it can be carried by a human and/or shipped. Example housings may include materials that form one or more exterior surfaces that partially or fully protect contents of the appliance, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs. AC/DC or DC/AC converter(s), power regulators, transformers, charging circuitry, batteries, wired inputs and/or wireless power inputs. Example housings and/or surfaces thereof may include or connect to mounting hardware to enable attachment to structures such as buildings, telecommunication structures (e.g., poles, antenna structures, etc.) and/or racks (e.g., server racks, blade mounts, etc.). Example housings and/or surfaces thereof may support one or more sensors (e.g., temperature sensors, vibration sensors, light sensors, acoustic sensors, capacitive sensors, proximity sensors, etc.). One or more such sensors may be contained in, carried by, or otherwise embedded in the surface and/or mounted to the surface of the appliance. Example housings and/or surfaces thereof may support mechanical connectivity, such as propulsion hardware (e.g., wheels, propellers, etc.) and/or articulating hardware (e.g., robot arms, pivotable appendages, etc.). In some circumstances, the sensors may include any type of input devices such as user interface hardware (e.g., buttons, switches, dials, sliders, etc.). In some circumstances, example housings include output devices contained in, carried by, embedded therein and/or attached thereto. Output devices may include displays, touchscreens, lights, LEDs, speakers, I/O ports (e.g., USB), etc. In some circumstances, edge devices are devices presented in the network for a specific purpose (e.g., a traffic light), but may have processing and/or other capacities that may be utilized for other purposes. Such edge devices may be independent from other networked devices and may be provided with a housing having a form factor suitable for its primary purpose; yet be available for other compute tasks that do not interfere with its primary task. Edge devices include Internet of Things devices. The appliance computing device may include hardware and software components to manage local issues such as device temperature, vibration, resource utilization, updates, power issues, physical and network security, etc. Example hardware for implementing an appliance computing device is described in conjunction with FIG. 4B. The edge cloud 110 may also include one or more servers and/or one or more multi-tenant servers. Such a server may include an operating system and implement a virtual computing environment. A virtual computing environment may include a hypervisor managing (e.g., spawning, deploying, destroying, etc.) one or more virtual machines, one or more containers, etc. Such virtual computing environments provide an execution environment in which one or more applications and/or other software, code or scripts may execute while being isolated from one or more other applications, software, code or scripts.

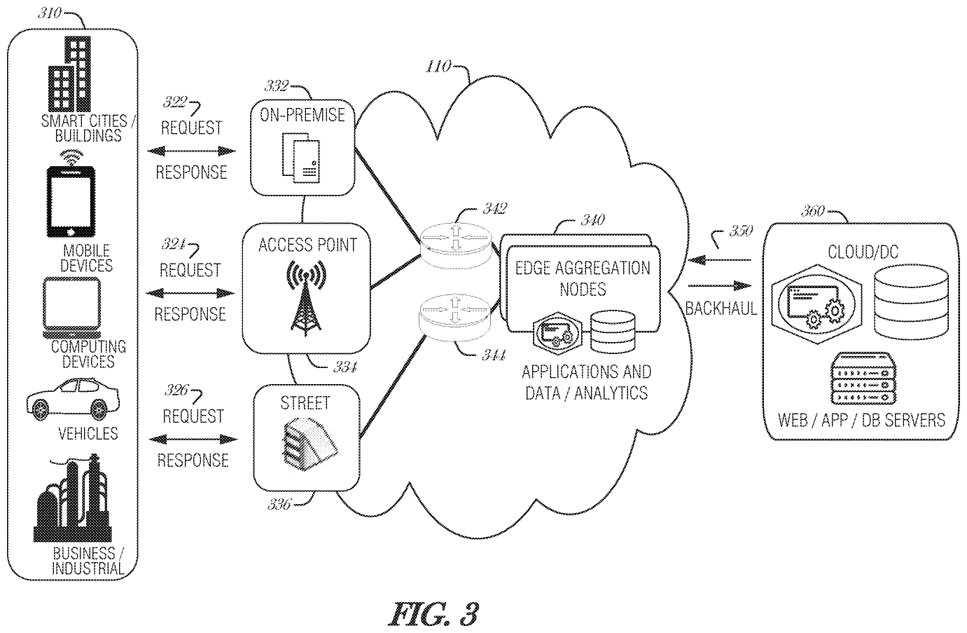

In FIG. 3, various client endpoints 310 (in the form of mobile devices, computers, autonomous vehicles, business computing equipment, industrial processing equipment) exchange requests and responses that are specific to the type of endpoint network aggregation. For instance, client endpoints 310 may obtain network access via a wired broadband network, by exchanging requests and responses 322 through an on-premise network system 332. Some client endpoints 310, such as mobile computing devices, may obtain network access via a wireless broadband network, by exchanging requests and responses 324 through an access point (e.g., cellular network tower) 334. Some client endpoints 310, such as autonomous vehicles may obtain network access for requests and responses 326 via a wireless vehicular network through a street-located network system 336. However, regardless of the type of network access, the TSP may deploy aggregation points 342, 344 within the edge cloud 110 to aggregate traffic and requests. Thus, within the edge cloud 110, the TSP may deploy various compute and storage resources, such as at edge aggregation nodes 340, to provide requested content. The edge aggregation nodes 340 and other systems of the edge cloud 110 are connected to a cloud or data center 360, which uses a backhaul network 350 to fulfill higher-latency requests from a cloud/data center for websites, applications, database servers, etc. Additional or consolidated instances of the edge aggregation nodes 340 and the aggregation points 342, 344, including those deployed on a single server framework, may also be present within the edge cloud 110 or other areas of the TSP infrastructure.

In further examples, any of the compute nodes or devices discussed with reference to the present edge computing systems and environment may be fulfilled based on the components depicted in FIGS. 4A and 4B. Respective edge compute nodes may be embodied as a type of device, appliance, computer, or other “thing” capable of communicating with other edge, networking, or endpoint components. For example, an edge compute device may be embodied as a personal computer, server, smartphone, a mobile compute device, a smart appliance, an in-vehicle compute system (e.g., a navigation system), a self-contained device having an outer case, shell, etc., or other device or system capable of performing the described functions.

In the simplified example depicted in FIG. 4A, an edge compute node 400 includes a compute engine (also referred to herein as “compute circuitry”) 402, an input/output (I/O) subsystem 408, data storage 410, a communication circuitry subsystem 412, and, optionally, one or more peripheral devices 414. In other examples, respective compute devices may include other or additional components, such as those typically found in a computer (e.g., a display, peripheral devices, etc.). Additionally, in some examples, one or more of the illustrative components may be incorporated in, or otherwise form a portion of, another component.

The compute node 400 may be embodied as any type of engine, device, or collection of devices capable of performing various compute functions. In some examples, the compute node 400 may be embodied as a single device such as an integrated circuit, an embedded system, a field-programmable gate array (FPGA), a system-on-a-chip (SoC), or other integrated system or device. In the illustrative example, the compute node 400 includes or is embodied as a processor 404 and a memory 406. The processor 404 may be embodied as any type of processor capable of performing the functions described herein (e.g., executing an application). For example, the processor 404 may be embodied as a multi-core processor(s), a microcontroller, a processing unit, a specialized or special purpose processing unit, or other processor or processing/controlling circuit.

In some examples, the processor 404 may be embodied as, include, or be coupled to an FPGA, an application specific integrated circuit (ASIC), reconfigurable hardware or hardware circuitry, or other specialized hardware to facilitate performance of the functions described herein. Also, in some examples, the processor 404 may be embodied as a specialized x-processing unit (xPU) also known as a data processing unit (DPU), infrastructure processing unit (IPU), or network processing unit (NPU). Such an xPU may be embodied as a standalone circuit or circuit package, integrated within an SoC, or integrated with networking circuitry (e.g., in a SmartNIC, or enhanced SmartNIC), acceleration circuitry, storage devices, or AI hardware (e.g., GPUs or programmed FPGAs). Such an xPU may be designed to receive programming to process one or more data streams and perform specific tasks and actions for the data streams (such as hosting microservices, performing service management or orchestration, organizing or managing server or data center hardware, managing service meshes, or collecting and distributing telemetry), outside of the CPU or general purpose processing hardware. However, it will be understood that a xPU, a SoC, a CPU, and other variations of the processor 404 may work in coordination with each other to execute many types of operations and instructions within and on behalf of the compute node 400.

The memory 406 may be embodied as any type of volatile (e.g., dynamic random access memory (DRAM), etc.) or non-volatile memory or data storage capable of performing the functions described herein. Volatile memory may be a storage medium that requires power to maintain the state of data stored by the medium. Non-limiting examples of volatile memory may include various types of random access memory (RAM), such as DRAM or static random access memory (SRAM). One particular type of DRAM that may be used in a memory module is synchronous dynamic random access memory (SDRAM).

In an example, the memory device is a block addressable memory device, such as those based on NAND or NOR technologies. A memory device may also include a three dimensional crosspoint memory device (e.g., Intel® 3D XPoint™ memory), or other byte addressable write-in-place nonvolatile memory devices. The memory device may refer to the die itself and/or to a packaged memory product. In some examples, 3D crosspoint memory (e.g., Intel® 3D XPoint™ memory) may comprise a transistor-less stackable cross point architecture in which memory cells sit at the intersection of word lines and bit lines and are individually addressable and in which bit storage is based on a change in bulk resistance. In some examples, all or a portion of the memory 406 may be integrated into the processor 404. The memory 406 may store various software and data used during operation such as one or more applications, data operated on by the application(s), libraries, and drivers.

The compute circuitry 402 is communicatively coupled to other components of the compute node 400 via the I/O subsystem 408, which may be embodied as circuitry and/or components to facilitate input/output operations with the compute circuitry 402 (e.g., with the processor 404 and/or the main memory 406) and other components of the compute circuitry 402. For example, the I/O subsystem 408 may be embodied as, or otherwise include, memory controller hubs, input/output control hubs, integrated sensor hubs, firmware devices, communication links (e.g., point-to-point links, bus links, wires, cables, light guides, printed circuit board traces, etc.), and/or other components and subsystems to facilitate the input/output operations. In some examples, the I/O subsystem 408 may form a portion of a system-on-a-chip (SoC) and be incorporated, along with one or more of the processor 404, the memory 406, and other components of the compute circuitry 402, into the compute circuitry 402.

The one or more illustrative data storage devices 410 may be embodied as any type of devices configured for short-term or long-term storage of data such as, for example, memory devices and circuits, memory cards, hard disk drives, solid-state drives, or other data storage devices. Individual data storage devices 410 may include a system partition that stores data and firmware code for the data storage device 410. Individual data storage devices 410 may also include one or more operating system partitions that store data files and executables for operating systems depending on, for example, the type of compute node 400.

The communication circuitry 412 may be embodied as any communication circuit, device, or collection thereof, capable of enabling communications over a network between the compute circuitry 402 and another compute device (e.g., an edge gateway of an implementing edge computing system). The communication circuitry 412 may be configured to use any one or more communication technology (e.g., wired or wireless communications) and associated protocols (e.g., a cellular networking protocol such a 3GPP 4G or 5G standard, a wireless local area network protocol such as IEEE 802.11/Wi-Fi®, a wireless wide area network protocol, Ethernet, Bluetooth®, Bluetooth Low Energy, a IoT protocol such as IEEE 802.15.4 or ZigBee®, low-power wide-area network (LPWAN) or low-power wide-area (LPWA) protocols, etc.) to effect such communication.

The illustrative communication circuitry 412 includes a network interface controller (NIC) 420, which may also be referred to as a host fabric interface (HFI). The NIC 420 may be embodied as one or more add-in-boards, daughter cards, network interface cards, controller chips, chipsets, or other devices that may be used by the compute node 400 to connect with another compute device (e.g., an edge gateway node). In some examples, the NIC 420 may be embodied as part of a system-on-a-chip (SoC that includes one or more processors, or included on a multichip package that also contains one or more processors. In some examples, the NIC 420 may include a local processor (not shown) and/or a local memory (not shown) that are both local to the NIC 420. In such examples, the local processor of the NIC 420 may be capable of performing one or more of the functions of the compute circuitry 402 described herein. Additionally, or alternatively, in such examples, the local memory of the NIC 420 may be integrated into one or more components of the client compute node at the board level, socket level, chip level, and/or other levels.

Additionally, in some examples, a respective compute node 400 may include one or more peripheral devices 414. Such peripheral devices 414 may include any type of peripheral device found in a compute device or server such as audio input devices, a display, other input/output devices, interface devices, and/or other peripheral devices, depending on the particular type of the compute node 400. In further examples, the compute node 400 may be embodied by a respective edge compute node (whether a client, gateway, or aggregation node) in an edge computing system or like forms of appliances, computers, subsystems, circuitry, or other components.

In a more detailed example, FIG. 4B illustrates a block diagram of an example of components that may be present in an edge computing node 450 for implementing the techniques (e.g., operations, processes, methods, and methodologies) described herein. This edge computing node 450 provides a closer view of the respective components of node 400 when implemented as or as part of a computing device (e.g., as a mobile device, a base station, server, gateway, etc.). The edge computing node 450 may include any combinations of the hardware or logical components referenced herein, and it may include or couple with any device usable with an edge communication network or a combination of such networks. The components may be implemented as integrated circuits (ICs), portions thereof, discrete electronic devices, or other modules, instruction sets, programmable logic or algorithms, hardware, hardware accelerators, software, firmware, or a combination thereof adapted in the edge computing node 450, or as components otherwise incorporated within a chassis of a larger system.

The edge computing node 450 may include processing circuitry in the form of a processor 452, which may be a microprocessor, a multi-core processor, a multithreaded processor, an ultra-low voltage processor, an embedded processor, an xPU/DPU/IPU/NPU, special purpose processing unit, specialized processing unit, or other known processing elements. The processor 452 may be a part of a system on a chip (SoC) in which the processor 452 and other components are formed into a single integrated circuit, or a single package, such as the Edison™ or Galileo™ SoC boards from Intel Corporation, Santa Clara, Calif. As an example, the processor 452 may include an Intel⁻ Architecture Core™ based CPU processor, such as a Quark™, an Atom™, an i3, an i5, an i7, an i9, or an MCU-class processor, or another such processor available from Intel. However, any number other processors may be used, such as available from Advanced Micro Devices. Inc. (AMD®) of Sunnyvale, Calif., a MIPS®-based design from MIPS Technologies, Inc. of Sunnyvale, Calif., an ARM®-based design licensed from ARM Holdings, Ltd. or a customer thereof, or their licensees or adopters. The processors may include units such as an A5-13 processor from Apple® Inc., a Snapdragon™ processor from Qualcomm® Technologies, Inc., or an OMAP™ processor from Texas Instruments, Inc. The processor 452 and accompanying circuitry may be provided in a single socket form factor, multiple socket form factor, or a variety of other formats, including in limited hardware configurations or configurations that include fewer than all elements shown in FIG. 4B.

The processor 452 may communicate with a system memory 454 over an interconnect 456 (e.g., a bus). Any number of memory devices may be used to provide for a given amount of system memory. As examples, the memory 454 may be random access memory (RAM) in accordance with a Joint Electron Devices Engineering Council (JEDEC) design such as the DDR or mobile DDR standards (e.g., LPDDR, LPDDR2, LPDDR3, or LPDDR4). In particular examples, a memory component may comply with a DRAM standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces. In various implementations, the individual memory devices may be of any number of different package types such as single die package (SDP), dual die package (DDP) or quad die package (Q17P). These devices, in some examples, may be directly soldered onto a motherboard to provide a lower profile solution, while in other examples the devices are configured as one or more memory modules that in turn couple to the motherboard by a given connector. Any number of other memory implementations may be used, such as other types of memory modules, e.g., dual inline memory modules (DTMMs) of different varieties including but not limited to microDIMMs or MiniDIMMs.

To provide for persistent storage of information such as data, applications, operating systems and so forth, a storage 458 may also couple to the processor 452 via the interconnect 456. In an example, the storage 458 may be implemented via a solid-state disk drive (SSDD). Other devices that may be used for the storage 458 include flash memory cards, such as Secure Digital (SD) cards, microSD cards, eXtreme Digital (XD) picture cards, and the like, and Universal Serial Bus (USB) flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

In low power implementations, the storage 458 may be on-die memory or registers associated with the processor 452. However, in some examples, the storage 458 may be implemented using a micro hard disk drive (HDD). Further, any number of new technologies may be used for the storage 458 in addition to, or instead of, the technologies described, such resistance change memories, phase change memories, holographic memories, or chemical memories, among others.

The components may communicate over the interconnect 456. The interconnect 456 may include any number of technologies, including industry standard architecture (ISA), extended ISA (EISA), peripheral component interconnect (PCI), peripheral component interconnect extended (PCIx), PCI express (PCIe), or any number of other technologies. The interconnect 456 may be a proprietary bus, for example, used in an SoC based system. Other bus systems may be included, such as an Inter-Integrated Circuit (I2C) interface, a Serial Peripheral Interface (SPI) interface, point to point interfaces, and a power bus, among others.

The interconnect 456 may couple the processor 452 to a transceiver 466, for communications with the connected edge devices 462. The transceiver 466 may use any number of frequencies and protocols, such as 2.4 Gigahertz (GHz) transmissions under the IEEE 802.15.4 standard, using the Bluetooth® low energy (BLE) standard, as defined by the Bluetooth® Special Interest Group, or the ZigBee® standard, among others. Any number of radios, configured for a particular wireless communication protocol, may be used for the connections to the connected edge devices 462. For example, a wireless local area network (WLAN) unit may be used to implement Wi-Fi® communications in accordance with the Institute of Electrical and Electronics Engineers (IEEE) 802.11 standard. In addition, wireless wide area communications, e.g., according to a cellular or other wireless wide area protocol, may occur via a wireless wide area network (WWAN) unit.

The wireless network transceiver 466 (or multiple transceivers) may communicate using multiple standards or radios for communications at a different range. For example, the edge computing node 450 may communicate with close devices, e.g., within about 10 meters, using a local transceiver based on Bluetooth Low Energy (BLE), or another low power radio, to save power. More distant connected edge devices 462, e.g., within about 50 meters, may be reached over ZigBee® or other intermediate power radios. Both communications techniques may take place over a single radio at different power levels or may take place over separate transceivers, for example, a local transceiver using BLE and a separate mesh transceiver using ZigBee®.

A wireless network transceiver 466 (e.g., a radio transceiver) may be included to communicate with devices or services in a cloud (e.g., an edge cloud 495) via local or wide area network protocols. The wireless network transceiver 466 may be a low-power wide-area (LPWA) transceiver that follows the IEEE 802.15.4, or IEEE 802.15.4g standards, among others. The edge computing node 450 may communicate over a wide area using LoRaWAN™ (Long Range Wide Area Network) developed by Semtech and the LoRa Alliance. The techniques described herein are not limited to these technologies but may be used with any number of other cloud transceivers that implement long range, low bandwidth communications, such as Sigfox, and other technologies. Further, other communications techniques, such as time-slotted channel hopping, described in the IEEE 802.15.4e specification may be used.

Any number of other radio communications and protocols may be used in addition to the systems mentioned for the wireless network transceiver 466, as described herein. For example, the transceiver 466 may include a cellular transceiver that uses spread spectrum (SPA/SAS) communications for implementing high-speed communications. Further, any number of other protocols may be used, such as Wi-Fi® networks for medium speed communications and provision of network communications. The transceiver 466 may include radios that are compatible with any number of 3GPP (Third Generation Partnership Project) specifications, such as Long Term Evolution (LTE) and 5th Generation (5G) communication systems, discussed in further detail at the end of the present disclosure. A network interface controller (NIC) 468 may be included to provide a wired communication to nodes of the edge cloud 495 or to other devices, such as the connected edge devices 462 (e.g., operating in a mesh). The wired communication may provide an Ethernet connection or may be based on other types of networks, such as Controller Area Network (CAN), Local Interconnect Network (LIN), DeviceNet, ControlNet, Data Highway+, PROFIBUS, or PROFINET, among many others. An additional NIC 468 may be included to enable connecting to a second network, for example, a first NIC 468 providing communications to the cloud over Ethernet, and a second NIC 468 providing communications to other devices over another type of network.

Given the variety of types of applicable communications from the device to another component or network, applicable communications circuitry used by the device may include or be embodied by any one or more of components 464, 466, 468, or 470. Accordingly, in various examples, applicable means for communicating (e.g., receiving, transmitting, etc.) may be embodied by such communications circuitry.

The edge computing node 450 may include or be coupled to acceleration circuitry 464, which may be embodied by one or more artificial intelligence (AI) accelerators, a neural compute stick, neuromorphic hardware, an FPGA, an arrangement of GPUs, an arrangement of xPUs/DPUs/IPU/NPUs, one or more SoCs, one or more CPUs, one or more digital signal processors, dedicated ASICs, or other forms of specialized processors or circuitry designed to accomplish one or more specialized tasks. These tasks may include AI processing (including machine learning, training, inferencing, and classification operations), visual data processing, network data processing, object detection, rule analysis, or the like. These tasks also may include the specific edge computing tasks for service management and service operations discussed elsewhere in this document.

The interconnect 456 may couple the processor 452 to a sensor hub or external interface 470 that is used to connect additional devices or subsystems. The devices may include sensors 472, such as accelerometers, level sensors, flow sensors, optical light sensors, camera sensors, temperature sensors, global navigation system (e.g., OPS) sensors, pressure sensors, barometric pressure sensors, and the like. The hub or interface 470 further may be used to connect the edge computing node 450 to actuators 474, such as power switches, valve actuators, an audible sound generator, a visual warning device, and the like.

In some optional examples, various input/output (I/O) devices may be present within or connected to, the edge computing node 450. For example, a display or other output device 484 may be included to show information, such as sensor readings or actuator position. An input device 486, such as a touch screen or keypad may be included to accept input. An output device 484 may include any number of forms of audio or visual display, including simple visual outputs such as binary status indicators (e.g., light-emitting diodes (LEDs)) and multi-character visual outputs, or more complex outputs such as display screens (e.g., liquid crystal display (LCD) screens), with the output of characters, graphics, multimedia objects, and the like being generated or produced from the operation of the edge computing node 450. A display or console hardware, in the context of the present system, may be used to provide output and receive input of an edge computing system; to manage components or services of an edge computing system; identify a state of an edge computing component or service; or to conduct any other number of management or administration functions or service use cases.

A battery 476 may power the edge computing node 450, although, in examples in which the edge computing node 450 is mounted in a fixed location, it may have a power supply coupled to an electrical grid, or the battery may be used as a backup or for temporary capabilities. The battery 476 may be a lithium ion battery, or a metal-air battery, such as a zinc-air battery, an aluminum-air battery, a lithium-air battery, and the like.

A battery monitor/charger 478 may be included in the edge computing node 450 to track the state of charge (SoCh) of the battery 476, if included. The battery monitor/charger 478 may be used to monitor other parameters of the battery 476 to provide failure predictions, such as the state of health (SoH) and the state of function (SoF) of the battery 476. The battery monitor/charger 478 may include a battery monitoring integrated circuit, such as an LTC4020 or an LTC2990 from Linear Technologies, an ADT7488A from ON Semiconductor of Phoenix Ariz., or an IC from the UCD90xxx family from Texas Instruments of Dallas, Tex. The battery monitor/charger 478 may communicate the information on the battery 476 to the processor 452 over the interconnect 456. The battery monitor/charger 478 may also include an analog-to-digital (ADC) converter that enables the processor 452 to directly monitor the voltage of the battery 476 or the current flow from the battery 476. The battery parameters may be used to determine actions that the edge computing node 450 may perform, such as transmission frequency, mesh network operation, sensing frequency, and the like.

A power block 480, or other power supply coupled to a grid, may be coupled with the battery monitor/charger 478 to charge the battery 476. In some examples, the power block 480 may be replaced with a wireless power receiver to obtain the power wirelessly, for example, through a loop antenna in the edge computing node 450. A wireless battery charging circuit, such as an LTC4020 chip from Linear Technologies of Milpitas, Calif., among others, may be included in the battery monitor/charger 478. The specific charging circuits may be selected based on the size of the battery 476, and thus, the current required. The charging may be performed using the Airfuel standard promulgated by the Airfuel Alliance, the Qi wireless charging standard promulgated by the Wireless Power Consortium, or the Rezence charging standard, promulgated by the Alliance for Wireless Power, among others.

The storage 458 may include instructions 482 in the form of software, firmware, or hardware commands to implement the techniques described herein. Although such instructions 482 are shown as code blocks included in the memory 454 and the storage 458, it may be understood that any of the code blocks may be replaced with hardwired circuits, for example, built into an application specific integrated circuit (ASIC).

In an example, the instructions 482 provided via the memory 454, the storage 458, or the processor 452 may be embodied as a non-transitory, machine-readable medium 460 including code to direct the processor 452 to perform electronic operations in the edge computing node 450. The processor 452 may access the non-transitory, machine-readable medium 460 over the interconnect 456. For instance, the non-transitory, machine-readable medium 460 may be embodied by devices described for the storage 458 or may include specific storage units such as optical disks, flash drives, or any number of other hardware devices. The non-transitory, machine-readable medium 460 may include instructions to direct the processor 452 to perform a specific sequence or flow of actions, for example, as described with respect to the flowchart(s) and block diagram(s) of operations and functionality depicted above. As used herein, the terms “machine-readable medium” and “computer-readable medium” are interchangeable.

Also, in a specific example, the instructions 482 on the processor 452 (separately, or in combination with the instructions 482 of the machine readable medium 460) may configure execution or operation of a trusted execution environment (TEE) 490. In an example, the TEE 490 operates as a protected area accessible to the processor 452 for secure execution of instructions and secure access to data. Various implementations of the TEE 490, and an accompanying secure area in the processor 452 or the memory 454 may be provided, for instance, through use of Intel Software Guard Extensions (SGX) or ARM® TrustZone® hardware security extensions, Intel® Management Engine (ME), or Intel Converged Security Manageability Engine (CSME). Other aspects of security hardening, hardware roots-of-trust, and trusted or protected operations may be implemented in the node 450 through the TEE 490 and the processor 452.

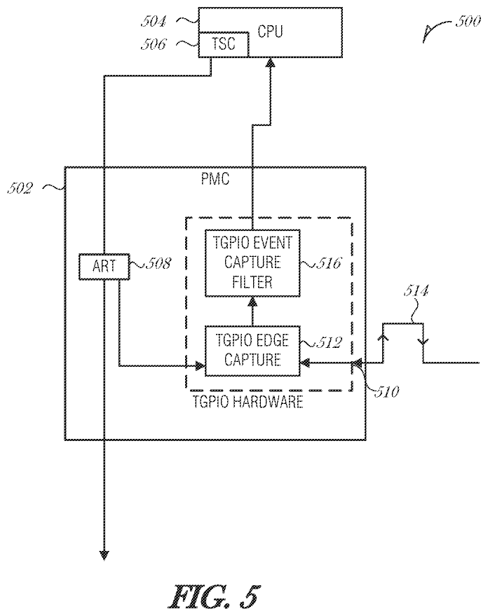

FIG. 5 is a block diagram illustrating a time-aware general-purpose input output (TGPIO) system 500, according to an embodiment. The TGPIO system 500 may be included on a PCI mezzanine card (PMC) 502 that is configured to communicate with a CPU 504 over a PCI bus. The CPU 504 includes a Time Stamp Counter (TSC) 506, which is the CPU clock. The TSC 506 is synchronized to an Always Running Timer (ART) 508 on the PMC 502. The TSC 506 is used for operating system level timekeeping. The ART 508 synchronizes other system devices (e.g., a network interface card) including other PCI connected devices.

Precision Time Measurement (PTM) enables precise coordination of events across multiple components with independent local time clocks. Such precise coordination would be difficult given that individual time clocks have differing notions of the value and rate of change of time. PTM allows components to calculate the relationship between their local times and a shared PTM Master Time: an independent time domain associated with a PTM Root.

For instance, PTM dialogs may be conducted between a downstream device and an upstream device. The downstream device has an upstream port through which the downstream device can send messages to an upstream device. The upstream device has a downstream port through which the upstream device can send messages to a downstream device. The upstream device can be embodied as a PCIe root port. The PTM dialog enables components with differing local time to calculate the relationship between their local times and a shared PTM Master Time (e.g., Time Stamp Counter (TSC)) associated with a PTM Root. The PTM Root is a PCIe Root Port that is the source of PTM Master Time for all the devices, such as downstream device and upstream device in the PCIe hierarchy associated with that Root port.

A TGPIO pin 510 on the TGPIO edge capture circuitry 512 is used to receive an input signal 514 driven by an external device. The TGPIO edge capture circuitry 512 may be designed, programmed, adapted, or otherwise configured to timestamp rising and falling edges (events) of a signal generated by an external device that is connected to the TGPIO input pin. The input signal may be periodic, for example, a GPS clock or aperiodic, for example, sensor input. It is understood that multiple TGPIO pins 510 may be used in TGPIO hardware. A TGPIO edge capture circuitry 512 may be implemented for each TGPIO pin 510. Edges of the input signal 514 are timestamped using the ART clock 508 and the CPU is notified of TGPIO events. An event is a rising edge, a falling edge, or sets of rising or falling edges of the input signal 514.

A TGPIO event capture filter circuitry 516 may be designed, programmed, adapted, or otherwise configured to search the events of the input signal for a pattern. The TGPIO event capture filter circuitry 516 recognizes patterns of timestamped events using the software provided input pattern specification (i.e., search pattern). The input pattern specification may be, for example, regular expressions or fuzzy logic rules. When a pattern is recognized the TGPIO event capture filter circuitry 516 returns only the timestamps that are of interest to the software application. A filter specification provided by application software specifies the events of interest. The search pattern may be provided by software executing on the CPU 504. This provides a software-specific filter in hardware.

TGPIO event filtering may be used in various applications. For instance, in the area of process monitoring and anomaly detection, PLCs in industrial automation are commonly used for motion control such as controlling the speed of precision motor controlling tools in a manufacturing facility. The system may be used to generate a digital twin from observed behavior providing a model for predicting machine failure. Then, the digital twin is used to generate input pattern recognition rules for TGPIO event filter. TGPIO hardware is able to notify an application of anomalous behavior (recognized pattern) that may lead to motor failure. The application is then able to handle exceptional behavior.

In a smart public utility grid context, the TGPIO device may be connected to a voltage sensor that captures patterns for voltage irregularity on the grid and logs anomalous voltage patterns on the grid informing the load balancing operations within the grid.

As another example implementation, the system may be used to detect clock drifts using trusted time sources. A device such as a sensor may be connected to common time source such as GPS that drives a sensor local device clock. If GPS is compromised (tampered with) on the sensor, the TOPIO hardware (connected to the sensor) can detect this by relating the timestamped events to a trusted local copy of the GPS clock (using ART). Anomalous timestamp patterns could indicate GPS tampering on the sensor which may indicate that any coordinates obtained from the sensor should also not be trusted. The system can detect tampering for any sensor that emits an edge pattern related to a common time source.

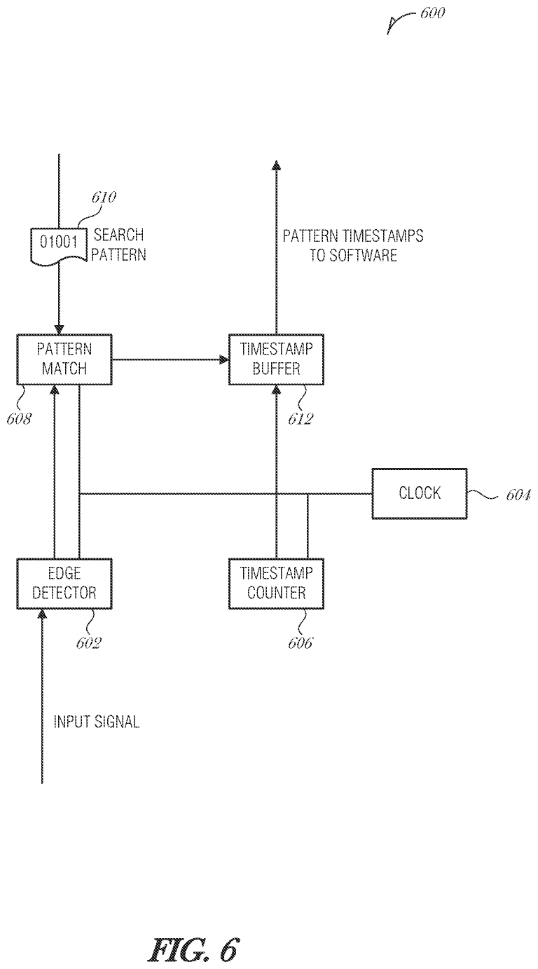

FIG. 6 is a block diagram illustrating an architecture 600 for implementing a time-aware general-purpose input output (TGPIO) system, according to an embodiment. An edge detector circuitry 602 may be designed, programmed, adapted, or otherwise configured to detect rising or falling edges of an input signal. The edge detector circuitry 602 outputs an indicator of a rising edge (R), a falling edge (F), or a no change (N) for each clock cycle. A device clock 604 is used to drive a timestamp counter 606.

As edge statuses are collected with the edge detector circuitry 602 and timestamps of each edge are stored in the timestamp buffer 612. Pattern match circuitry 608 may be designed, programmed, adapted, or otherwise configured to analyze the edges stored in the timestamp buffer 612 for a pattern. The search pattern 610 may be specified by software. When a pattern in the edges is detected, the timestamps for the related edges are sent to a user application or other software (e.g., operating system). The timestamp buffer 612 may be implemented as a circular buffer.

In an embodiment, the search pattern 610 is in the form of a regular expression. In another embodiment, the search pattern 610 is in the form of fuzzy logic rules that are implemented at the pattern match circuitry 608. Alternatively, the search pattern 610 may be implemented as a finite state automaton (FSA).

When a pattern is detected, the timestamp corresponding to the pattern obtained from the timestamp counter 606 is stored in a queue in the timestamp buffer 612. The software may be alerted of the pattern's existence or the software may poll the timestamp buffer 612 to determine which patterns have been buffered.

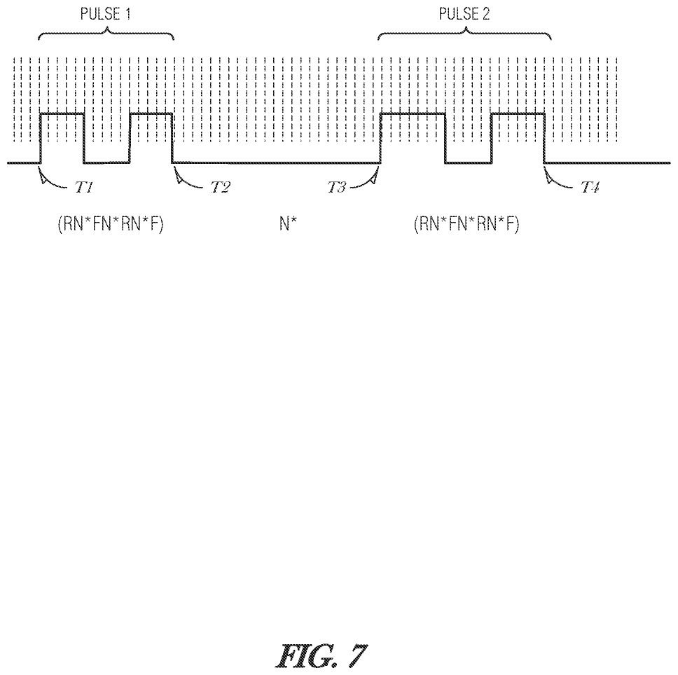

FIG. 7 is a diagram illustrating a series of pulses in a signal, according to an embodiment. The pulses include a rising edge at time T1, a falling edge at time T2, a rising edge at time T3, and a falling edge at time T4. The diagram includes the clock ticks illustrated as vertical dashed lines. As can be observed, some of the periods of no change (either high or low signal) have different durations.

A search pattern is provided in the form of a regular expression.

(RN*FN*RN*F)N*(RN*FN*RN*F)

where R is a rising edge, N is a no-change state, and F is a falling edge. The parenthesis in the search pattern are used to denote timestamps of interest. Based on the regular expression, the search pattern is a rising edge followed by zero or more no-change states, followed by a falling edge, followed by zero or more no-change states, etc. Any pattern of four pulses in the signal will match this example regular expression. Based on the parenthesis, the timestamps T1, T2, T3, and T4 are identified and stored when the pattern is matched. More specific ranges may be placed on the states to narrow the range of patterns that match.

Other examples of regular expressions include:

(RN{4}F)—this pattern will match a rising edge followed by four clock cycles of no-change states, then a falling edge;

(RN+F)—this pattern will match a rising edge followed by one or more no-change states, then a falling edge; and

(RN{3,6}F)—this pattern will match a rising edge followed by between three and six no-change states, then a falling edge.

It is understood that these examples are non-limiting and that other regular expression syntax may be used to form a search pattern.

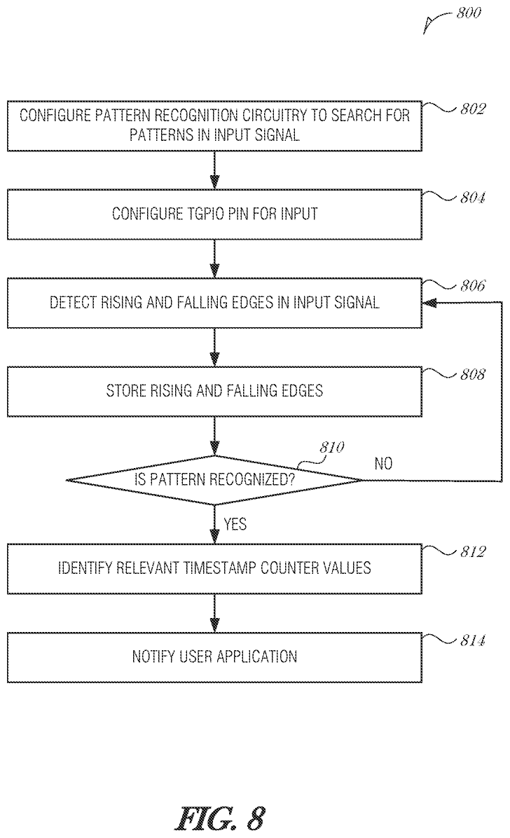

FIG. 8 is a flowchart illustrating a TGPIO filter process 800, according to an embodiment. At 802, a pattern recognition circuitry is configured to search for and recognize one or more patterns of TGPIO events. At 804, a TGPIO pin is configured for input. At 806, rising and falling edges of an input signal received over the TGPIO pin are detected. At 808, the edge type (e.g., rising or falling) and the corresponding timestamp are stored. The timestamp may be from an ART. At 810, pattern recognition is run on the timestamped edges. Based on the search patterns, the pattern recognition may be performed on all edges, on just rising edges, or on just falling edges. The pattern recognition uses a sliding search window, which may be configurable. The sliding window may be based on the size of the search pattern, the matching algorithm used, and available memory to store state. For example, a regular expression may be derived to match an arbitrarily long string. The matching algorithm, in this case, is not limited by string size, but by memory required to store the amount of state that needs to be kept in order to find a match.

As such, the size of the sliding window may be based on the size of the pattern. For instance, if a pattern involved 13 cycles, then the signal is sampled from a first edge for 13 cycles, and if a pattern is found, the application is notified. If not, then the next edge that matches the first element in the pattern is used and the subsequent 13 cycles (e.g., window) are searched for the pattern.

Once a pattern is recognized, relevant timestamp counter values are identified (operation 812) and a user application is notified (operation 814).

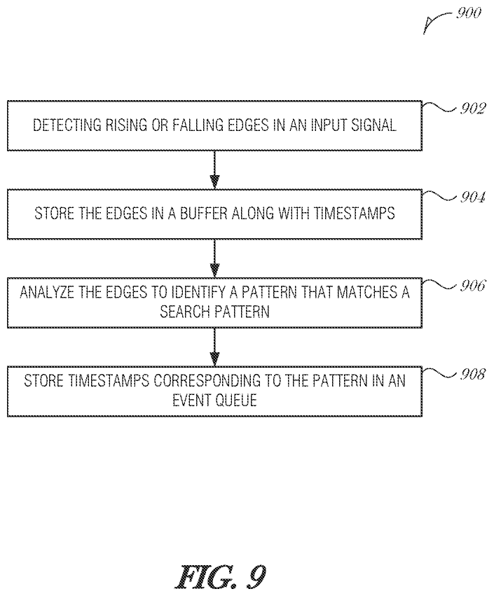

FIG. 9 is a flowchart illustrating a method 900 for searching TGPIO signals for patterns, according to an embodiment. At 902, rising or falling edges in an input signal are detected. In an embodiment, the input signal is from an external device.

At 904, the rising or falling edges are stored in a buffer along with a corresponding timestamp of the respective edge.

At 906, the rising or falling edges in the buffer are analyzed to identify a pattern of edges that matches a search pattern.

In an embodiment, the search pattern is provided by the user application. In an embodiment, the search pattern includes a regular expression. In a further embodiment, the regular expression includes a pattern of rising edges, falling edges, and no-change during clock cycles while the input signal is received. In an embodiment, the search pattern includes fuzzy logic rules. In an embodiment, the search pattern includes a finite state automaton.

At 908, timestamps corresponding to the pattern of edges are stored in an event queue, where the event queue used to notify a user application of the existence of the pattern of edges in the input signal.

As discussed above, a timestamp buffer 612 may be used to store timestamped events. The buffer may take the data structure of a queue. Software reads events from the queue as it is filled by the TGPIO hardware. In some TOPIO systems, when the queue used to hold TOPIO events overflows, arbitrary events from the queue are flushed or new events may be ignored and not queued. This can be problematic for customer applications that are waiting for an event.

A queue management engine is used to prevent overflow of TGPIO events. The queue management engine may compress events in a way to efficiently store events such that information is not lost.

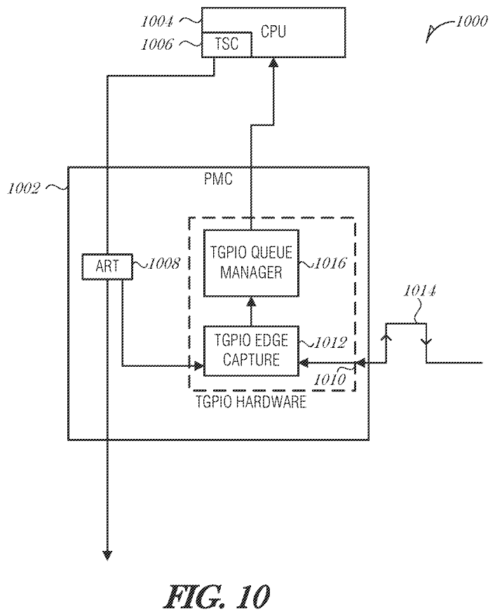

FIG. 10 is a block diagram illustrating a time-aware general-purpose input output (TGPIO) system 1000, according to an embodiment. The TGPIO system 1000 may include on a PCI mezzanine card (PMC) 1002 that is configured to communicate with a CPU 1004 over a PCI bus. The CPU 1004 includes a TSC 1006, which is the CPU clock. The TSC 1006 is synchronized to an ART 1008 on the PMC 1002. The TSC 1006 is used for operating system level timekeeping. The ART 1008 synchronizes other system devices (e.g., a network interface card) including other PCI connected devices.

A TGPIO pin 1010 on the TGPIO edge capture circuitry 1012 is used to receive an input signal 1014 driven by an external device. The TGPIO edge capture circuitry 1014 may be designed, programmed, adapted, or otherwise configured to timestamp rising and falling edges (events) of a signal generated by an external device that is connected to the TGPIO input pin. It is understood that multiple TGPIO pins 1010 may be used in TGPIO hardware. A TGPIO edge capture circuitry 1012 may be implemented for each TGPIO pin 1010. The input signal may be periodic, for example, a GPS clock or aperiodic, for example, sensor input. Edges of the input signal 1014 are timestamped using the ART clock 1008 and the CPU 1004 is notified of TGPIO events. An event is a rising edge, a falling edge, or sets of rising or falling edges of the input signal 1014.

A TGPIO queue manager circuitry 1016 may be designed, programmed, adapted, or otherwise configured to detect when queue overflow may occur and compress or reorganize the queue. The TGPIO queue manager circuitry 1016 monitors a rate of incoming events and the status of the event queue. When overflow is imminent, the TGPIO queue manager circuitry 1016 may utilize one or more compression techniques while ensuring that critical information in the event queue is preserved.

At the lowest level, the TGPIO hardware captures rising or falling edges with a timestamp. This generates a stream of timestamps corresponding to each captured edge. The queue may store groups of timestamps from the timestamp stream using user-specified timestamp groupings. For example, a two-pulse pattern can be placed into the queue as a four-timestamp grouping of when rising and falling edges occurred.

In general, the TOPIO queue manager circuitry 1016 may implement one of two types of compression methods: intergroup compression and intragroup compression.

Intergroup compression refers to discarding entire groups of timestamps based on a user-defined queue threshold. The group of timestamps to be discarded is dynamically determined based on rules provided by the user. The rules may be based on fuzzy logic or machine-learning parameters provided by the user.

Intergroup compression may be based on an arrival time of timestamp groups. If the difference in arrival time of the two most recent timestamp groups is smaller than a threshold set by the user, then the newest entry can be discarded. This enforces time distribution of captured timestamp groups.

Intergroup compression may be based on a difference of timestamps. If the difference between the first and last timestamp of a timestamp grouping is smaller than an average, then the timestamp group can be discarded. For instance, over several previous timestamp groups, an average time delta between a first and last timestamp may be established. If the timestamp group has a smaller interval than the average, then it may be discarded.

Intergroup compression may be implemented by recognizing anomalous data, which may be data of interest. In an implementation, the timestamp deltas within a group are inputted to a trained artificial intelligence (AI) to recognize potentially anomalous behavior. Timestamp groups that indicate anomalous behavior are enqueued to the application and others are dropped. This mechanism provides an efficient way to capture data anomalies.

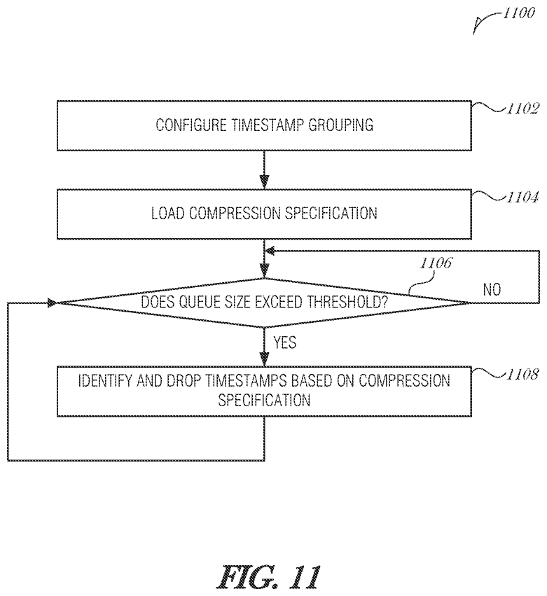

FIG. 11 is a flowchart illustrating a process 1100 to manage a TGPIO queue, according to an embodiment. At 1102, timestamp grouping is configured. For instance, timestamp grouping may be set to include four timestamps, ten timestamps, or some other number of timestamps that are considered together as a timestamp group.

At 1104, a compression specification is loaded. The compression specification is the set of rules or machine learning parameters to determine which timestamp groups should be dropped.

At 1106, queue size is monitored to determine the number of elements (queue size) exceed a threshold. The threshold may be a percentage size of the queue (e.g., 60% full, 80% full, or the like). The threshold may be a specific number, such as 92 elements. The threshold may be adaptively based on the rate of entries added or removed from the queue. For instance, a queue that grows slower may have a higher threshold (e.g., 90% full), than a queue that grows faster (e.g., 75% full).

At 1108, if the queue size exceeds the threshold, then a queue manager examines the event timestamps and based on the compression specification, drops one or more timestamp groups. The queue manager continues to monitor the queue size. In an embodiment, when even after dropping some timestamp groups, the queue is still too full, additional timestamp groups are discarded. In an embodiment, the oldest timestamp group is discarded first.

One example of an inter-group compression policy is keeping the n-th oldest set of timestamp groups. This is useful for applications that need to retain the oldest timestamps to compute average timestamp durations over the entire queue. The application specifies the set size of the oldest timestamps to preserve. If the oldest set size is one, the oldest timestamp group is preserved and timestamps starting at the second position are discarded when the queue is full or near full. If oldest set size is two, the two oldest groups are preserved and those starting from the third position are discarded. The user can specify up to oldest set size n, where n is the total number of timestamp groups (m) that can be enqueued. If the user specifies oldest set size as n=m, the newest timestamp is discarded when the queue is filled.

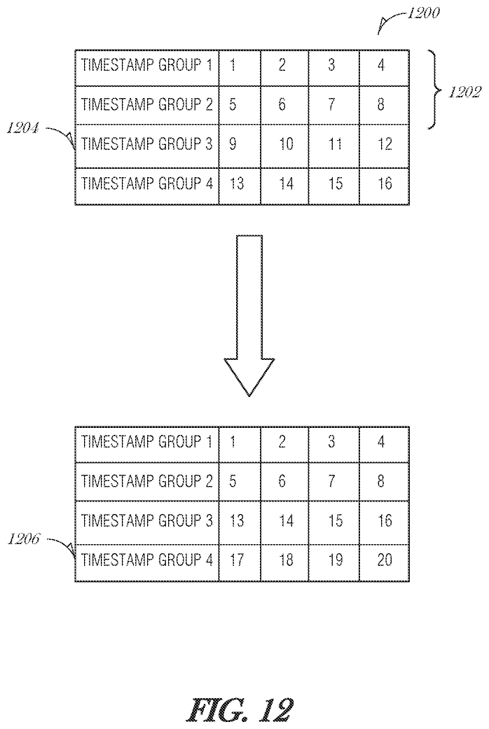

FIG. 12 shows the policy of preserving the Nth oldest entries in a queue 1200, where N=2. Because N=2, the first two entries 1202 are designated to be preserved. When the queue 1200 is full and a new timestamp group is captured, the third queue entry 1204 is discarded to make room for the new entry 1206. This can be used for applications that need to calculate frequency trends. The first two entries 1202 can be used to calculate an initial event rate and the last two entries are used to determine the final event rate.

Another example of intergroup compression uses machine learning to predict motor failure. The TGPIO hardware samples motor position and using machine learning determines whether the calculated rotation rate indicates some anomalous behavior. Any event groupings that indicate expected behavior are dropped. Other event groupings that indicate potentially anomalous behavior are queued to the application for further processing.

Intragroup compression is a method that discards timestamps within a group based on priorities or rules provided by a user. This compression method is useful when all timestamps in the pattern are not of critical importance. Compression can be used to discard some of the timestamps. This is different from the intergroup compression, which drops entire groups of timestamps.

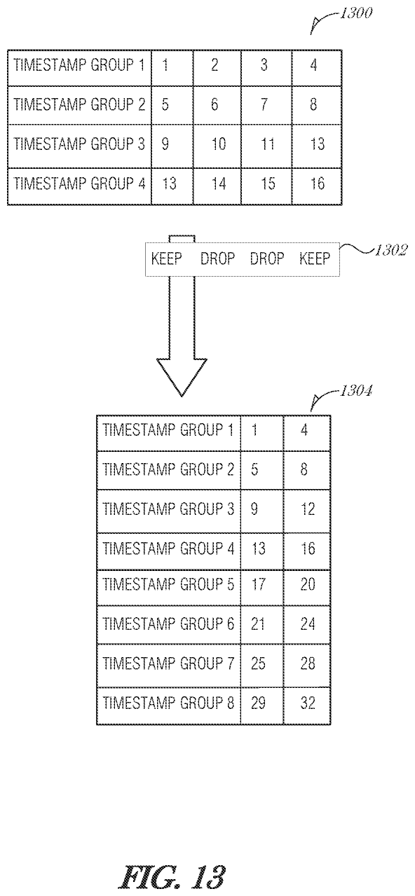

FIG. 13 is a diagram illustrating intragroup compression, according to an embodiment. A queue 1300 includes four timestamp groups, each group having four timestamps numbered one through sixteen. The four timestamps in a group align with a first rising edge, a first falling edge, a second rising edge, and a second falling edge across two pulses.

A drop mask 1302 may be defined to discard the middle two timestamps (the first falling edge and the second rising edge) and keep the first and fourth timestamps. The drop mask 1302 may be defined this way because the application that is using the timestamp data may be able to operate using the first and last timestamps. The middle timestamps may be useful but have a lower priority than the first and last timestamps.

The queue 1300 is reconfigured to a reconfigured queue 1304 to drop the middle two timestamps, which provides additional queue size for four more timestamp groups. The reconfigured queue 1304 is able to store timestamp groups with timestamps (17, 20), (21, 24), (25, 28), and (29,32). Note that the middle two timestamps are dropped before storing the timestamp group in the reconfigured queue 1304.

After the queue 1300 is reconfigured to the reconfigured queue 1304, the TGPIO hardware communicates with the software application to notify the application that the queue structure has changed. This allows the software to correct interpret the queue contents as timestamp groups are dequeued.

Drop masks may be static or dynamic. A static drop mask is one that specifies a fixed set of timestamps to be dropped in a group. An example static drop mask on a four-timestamp group is one that indicates to {keep, drop, drop, keep}, to indicate that the first and last timestamps are designed to keep, while dropping the second and third timestamps. Other example static drop masks may be {keep, drop, keep, keep}, {keep, drop, drop, drop}, or {keep, keep, drop, drop}. It is understood that many other static drop masks may be used, and they may be arranged to be applied in a series. For example, a first static drop mask may be used to move from a six-timestamp to a four-timestamp group, and then another static drop mask may be used to move from a four-timestamp group to a two-timestamp group if there is still queue pressure.

A dynamic drop mask is one that is defined using a dynamically configured drop mask. In this class of compression, timestamps in a group are dropped by modifying the mask dynamically based on methods such as machine learning or fuzzy logic. Here, timestamps are analyzed with a deep learning or fuzzy logic model, which then configured the drop mask.

Each compression pass can be either static or dynamic compression. For example, a first compression pass over the queue can use a static drop mask. A second pass over the queue can then use a dynamic drop mask.

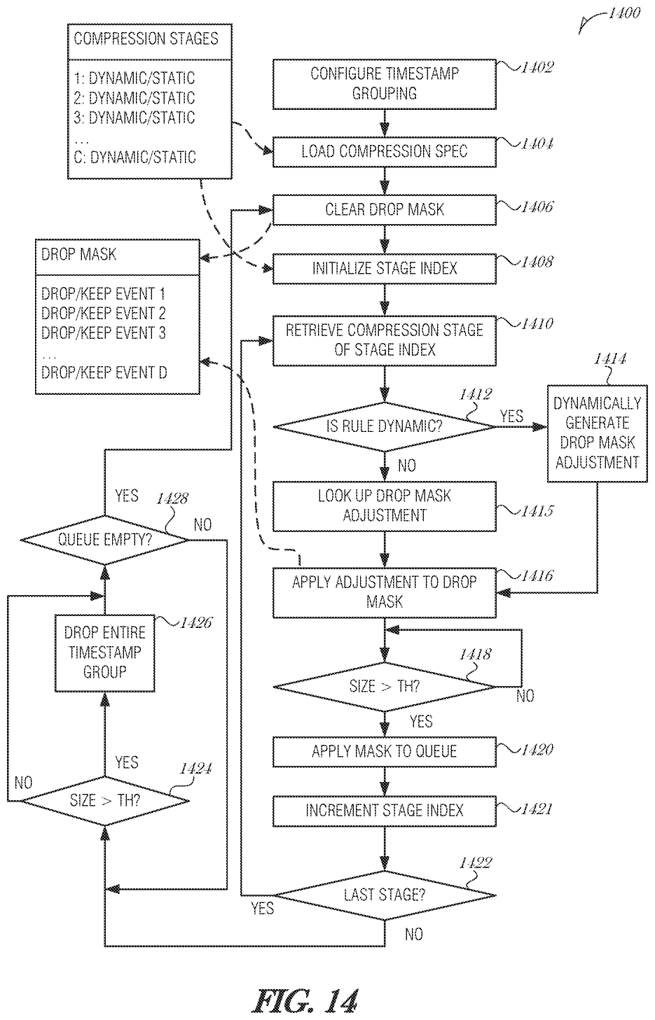

FIG. 14 is a flowchart illustrating a method 1400 for timestamp queue management, according to an embodiment. At initialization, the user application provides a timestamp group specification and a compression specification. The compression specification may include multiple passes or stages numbered 1 through C. The timestamps are dropped from a group based on the mask with a keep/drop specification for each timestamp in the group. Drop masks are numbered 1 through D. Each compression pass may make changes to the last used mask. The currently set drop mask is applied to all (past and future) captured event groupings.

At 1402, timestamp grouping is configured. For instance, timestamp grouping may be set to include four timestamps, ten timestamps, or some other number of timestamps that are considered together as a timestamp group.

At 1404, a compression specification is loaded. The compression specification includes a set of rules or machine learning parameters to determine which timestamp groups should be dropped. The compression specification also includes a list of compression stages specifying the order that the stages are applied. Each compression stage is associated with a drop mask. The compression stages are either static or dynamic, and the corresponding drop mask is either a static drop mask or a dynamic drop mask.

At 1406, the operative drop mask is cleared so that all timestamp entries are set to be kept. At 1408, the compression stage index is reset to the first stage.

At 1410, the compression stage corresponding to the stage index is accessed from the compression specification. If the compression stage is a dynamic stage (decision 1412), then a drop mask adjustment is dynamically generated (operation 1414). Otherwise, the drop mask adjustment is looked up in the drop mask list (operation 1415). The drop mask adjustment alters the drop mask from the initial configuration of “keep all timestamps” to a different mask configuration. If additional mask adjustments are made, they are made to the current mask as it has been altered by any previous drop mask adjustments. At 1416, the drop mask adjustment is applied to the drop mask, resulting in a new operative drop mask.

At 1418, the queue is monitored to determine whether the queue size (number of entries in the queue) has exceeded a threshold size. This monitoring is repeated in a loop. The queue may be monitored using a polling system that polls the queue at regular intervals. Alternatively, an enqueue operation may check the size of the queue when adding a new timestamp group to the queue and signal when the queue is over the threshold size.

If the queue is determined to be over the threshold size, then the operative drop mask is applied to the queue (operation 1420). The compression stage index is incremented so that the next time through the loop, the next compression stage is used to further compress the queue, if possible (operation 1421).

At decision block 1422, it is determined whether the current compression stage index is the last compression stage index. If it is, then the loop exits. If not, then the loop returns to operation 1410, where the next compression stage is accessed from the compression specification. After each compression pass, queue utilization is checked to determine if further compression is needed. If the queue utilization exceeds the threshold, then the next compression pass is applied to the mask. Each compression pass modifies the mask. A compression stage/pass is classified as static or dynamic. The drop mask is further adjusted based on a dynamic or static method, and applied to further compress the queue.

After all of the compression stages have been exhausted, there is no more compression available and the loop exits. If it is then determined that the queue exceeds the size threshold (decision 1424), then all that can be done is to remove entire timestamp groups (operation 1426). Timestamp groups are removed when there is queue pressure. The timestamp group to be removed may be based on the same rules used in the intergroup compression (e.g., intervals between timestamps in a group compared to other intervals from other groups). In another implementation, the oldest timestamp group may be removed first. Other policies may be used to remove timestamp groups based on priority level, age, or the like. This continues until the queue is emptied (decision 1428). Additionally, or optionally, the method 1100 of intergroup compression may be used on the queue to relieve queue pressure. Once emptied, the compression mechanism can be completely reset by resetting the drop mask (operation 1406) and resetting the compression stage index (operation 1408).

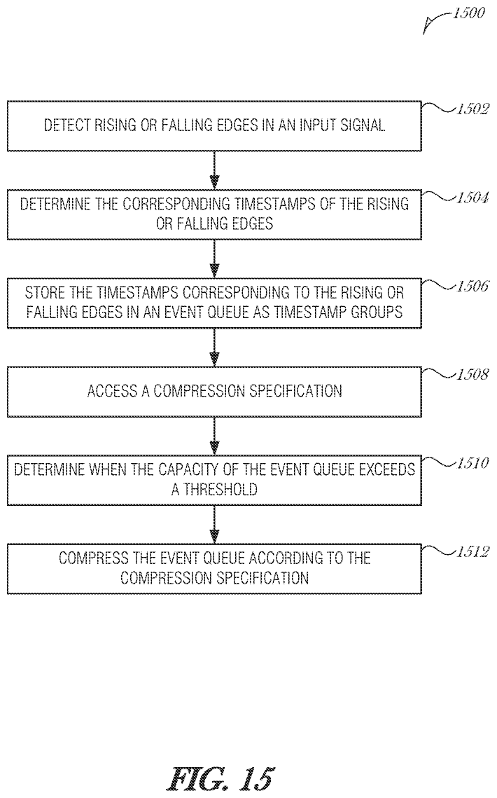

FIG. 15 is a flowchart illustrating a method 1500 for time-aware general purpose input/output signal compression, according to an embodiment.

At 1502, rising or falling edges in an input signal are detected.

At 1504, the corresponding timestamps of the rising or falling edges are determined.

At 1506, the timestamps corresponding to the rising or falling edges are stored in an event queue as timestamp groups according to a timestamp grouping configuration.

At 1508, a compression specification is accessed.

At 1510, it is determined when the capacity of the event queue exceeds a threshold.

At 1512, the event queue is compressed according to the compression specification, the event queue used to notify a user application.

In an embodiment, compressing the event queue comprises dropping a timestamp group from the queue. In a further embodiment, the compression specification includes group priorities to determine which timestamp group to drop from the queue. In a further embodiment, the group priorities include a number N of timestamp groups to preserve at the head of the queue.

In an embodiment, compressing the event queue comprises dropping a timestamp from a timestamp group. In a further embodiment, the compression specification includes a drop mask to indicate which timestamp to drop from a timestamp group. In a further embodiment, the drop mask is static drop mask. In another embodiment, the drop mask is provided by the user application.

In a related embodiment, the drop mask is a dynamic drop mask. In a further embodiment, the dynamic drop mask is modified at run time using a machine learning process. In another embodiment, the dynamic drop mask is modified at run time using a fuzzy logic process.

In an embodiment, compressing the event queue comprises reducing the size of a timestamp group.

Embodiments may be implemented in one or a combination of hardware, firmware, and software. Embodiments may also be implemented as instructions stored on a machine-readable storage device, which may be read and executed by at least one processor to perform the operations described herein. A machine-readable storage device may include any non-transitory mechanism for storing information in a form readable by a machine (e.g., a computer). For example, a machine-readable storage device may include read-only memory (ROM), random-access memory (RAM), magnetic disk storage media, optical storage media, flash-memory devices, and other storage devices and media.

Examples, as described herein, may include, or may operate on, logic or a number of components, such as modules, intellectual property (IP) blocks or cores, or mechanisms. Such logic or components may be hardware, software, or firmware communicatively coupled to one or more processors in order to carry out the operations described herein. Logic or components may be hardware modules (e.g., IP block), and as such may be considered tangible entities capable of performing specified operations and may be configured or arranged in a certain manner. In an example, circuits may be arranged (e.g., internally or with respect to external entities such as other circuits) in a specified manner as an IP block, IP core, system-on-chip (SoC), or the like.

In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations. Accordingly, the term hardware module is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein.

Considering examples in which modules are temporarily configured, each of the modules need not be instantiated at any one moment in time. For example, where the modules comprise a general-purpose hardware processor configured using software; the general-purpose hardware processor may be configured as respective different modules at different times. Software may accordingly configure a hardware processor, for example, to constitute a particular module at one instance of time and to constitute a different module at a different instance of time. Modules may also be software or firmware modules, which operate to perform the methodologies described herein.

An IP block (also referred to as an IP core) is a reusable unit of logic, cell, or integrated circuit. An IP block may be used as a part of a field programmable gate array (FPGA), application-specific integrated circuit (ASIC), programmable logic device (PLD), system on a chip (SoC), or the like. It may be configured for a particular purpose, such as digital signal processing or image processing. Example IP cores include central processing unit (CPU) cores, integrated graphics, security, input/output (I/O) control, system agent, graphics processing unit (GPU), artificial intelligence, neural processors, image processing unit, communication interfaces, memory controller, peripheral device control, platform controller hub, or the like.

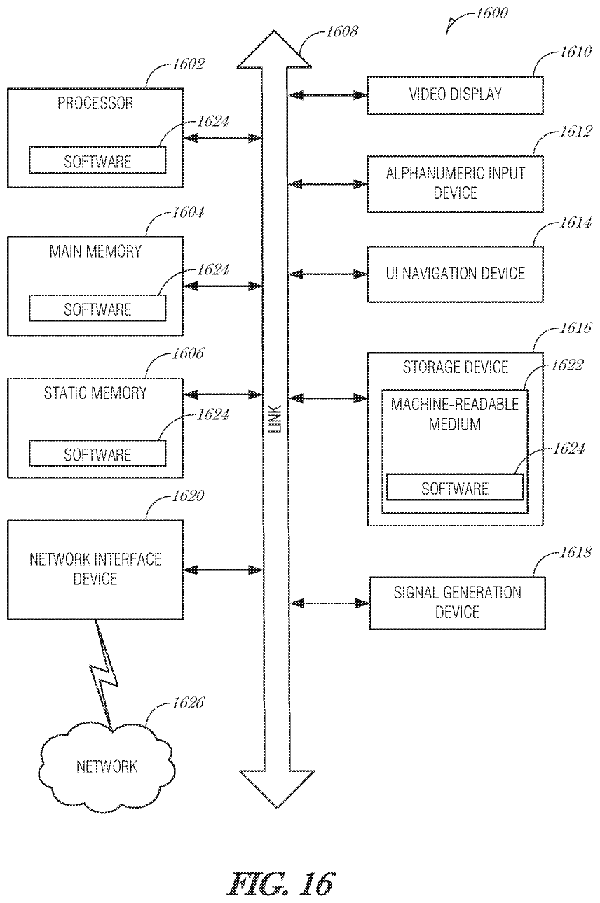

FIG. 16 is a block diagram illustrating a machine in the example form of a computer system 1600, within which a set or sequence of instructions may be executed to cause the machine to perform any one of the methodologies discussed herein, according to an example embodiment. In alternative embodiments, the machine operates as a standalone device or may be connected (e.g., networked) to other machines. In a networked deployment, the machine may operate in the capacity of either a server or a client machine in server-client network environments, or it may act as a peer machine in peer-to-peer (or distributed) network environments. The machine may be an onboard vehicle system, set-top box, wearable device, personal computer (PC), a tablet PC, a hybrid tablet, a personal digital assistant (PDA), a mobile telephone, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein. Similarly, the term “processor-based system” shall be taken to include any set of one or more machines that are controlled by or operated by a processor (e.g., a computer) to individually or jointly execute instructions to perform any one or more of the methodologies discussed herein.

Example computer system 1600 includes at least one processor 1602 (e.g., a central processing unit (CPU), a graphics processing unit (GPU) or both, processor cores, compute nodes, etc.), a main memory 1604 and a static memory 1606, which communicate with each other via a link 1608 (e.g., bus). The computer system 1600 may further include a video display unit 1610, an alphanumeric input device 1612 (e.g., a keyboard), and a user interface (UI) navigation device 1614 (e.g., a mouse). In one embodiment, the video display unit 1610, input device 1612 and UI navigation device 1614 are incorporated into a touch screen display. The computer system 1600 may additionally include a storage device 1616 (e.g., a drive unit), a signal generation device 1618 (e.g., a speaker), a network interface device 1620, and one or more sensors (not shown), such as a global positioning system (GPS) sensor, compass, accelerometer, or other sensor.

The storage device 1616 includes a machine-readable medium 1622 on which is stored one or more sets of data structures and instructions 1624 (e.g., software) embodying or utilized by any one or more of the methodologies or functions described herein. The instructions 1624 may also reside, completely or at least partially, within the main memory 1604, static memory 1606, and/or within the processor 1602 during execution thereof by the computer system 1600, with the main memory 1604, static memory 1606, and the processor 1602 also constituting machine-readable media.

While the machine-readable medium 1622 is illustrated in an example embodiment to be a single medium, the term “machine-readable medium” may include a single medium or multiple media (e.g., a centralized or distributed database, and/or associated caches and servers) that store the one or more instructions 1624. The term “machine-readable medium” shall also be taken to include any tangible medium that is capable of storing, encoding or carrying instructions for execution by the machine and that cause the machine to perform any one or more of the methodologies of the present disclosure or that is capable of storing, encoding or carrying data structures utilized by or associated with such instructions. The term “machine-readable medium” shall accordingly be taken to include, but not be limited to, solid-state memories, and optical and magnetic media. Specific examples of machine-readable media include non-volatile memory, including but not limited to, by way of example, semiconductor memory devices (e.g., electrically programmable read-only memory (EPROM), electrically erasable programmable read-only memory (EEPROM)) and flash memory devices; magnetic disks such as internal hard disks and removable disks; magneto-optical disks; and CD-ROM and DVD-ROM disks.

The instructions 1624 may further be transmitted or received over a communications network 1626 using a transmission medium via the network interface device 1620 utilizing any one of a number of well-known transfer protocols (e.g., HTTP). Examples of communication networks include a local area network (LAN), a wide area network (WAN), the Internet, mobile telephone networks, plain old telephone (POTS) networks, and wireless data networks (e.g., Wi-Fi, 3G, and 4G LTE/LTE-A or WiMAX networks). The term “transmission medium” shall be taken to include any intangible medium that is capable of storing, encoding, or carrying instructions for execution by the machine, and includes digital or analog communications signals or other intangible medium to facilitate communication of such software.

### Additional Notes & Examples

Example 1 is a system for searching time-aware general purpose input/output signals for patterns, comprising: edge detector circuitry to: detect rising or falling edges in an input signal; and store the rising or falling edges in a buffer along with a corresponding timestamp of the respective edge; and pattern match circuitry to: analyze the rising or falling edges in the buffer to identify a pattern of edges that matches a search pattern; and store timestamps corresponding to the pattern of edges in an event queue, the event queue used to notify a user application of the existence of the pattern of edges in the input signal.

In Example 2, the subject matter of Example 1 includes, wherein the input signal is from an external device.

In Example 3, the subject matter of Examples 1-2 includes, wherein the search pattern is provided by the user application.

In Example 4, the subject matter of Examples 1-3 includes, wherein the search pattern includes a regular expression.

In Example 5, the subject matter of Example 4 includes, wherein the regular expression includes a pattern of rising edges, falling edges, and no-change during clock cycles while the input signal is received.

In Example 6, the subject matter of Examples 1-5 includes, wherein the search pattern includes fuzzy logic rules.

In Example 7, the subject matter of Examples 1-6 includes, wherein the search pattern includes a finite state automaton.

Example 8 is a method for searching time-aware general purpose input/output signals for patterns, comprising: detecting rising or falling edges in an input signal; storing the rising or falling edges in a buffer along with a corresponding timestamp of the respective edge; analyzing the rising or falling edges in the buffer to identify a pattern of edges that matches a search pattern; and storing timestamps corresponding to the pattern of edges in an event queue, the event queue used to notify a user application of the existence of the pattern of edges in the input signal.

In Example 9, the subject matter of Example 8 includes, wherein the input signal is from an external device.

In Example 10, the subject matter of Examples 8-9 includes, wherein the search pattern is provided by the user application.

In Example 11, the subject matter of Examples 8-10 includes, wherein the search pattern includes a regular expression.

In Example 12, the subject matter of Example 11 includes, wherein the regular expression includes a pattern of rising edges, falling edges, and no-change during clock cycles while the input signal is received.

In Example 13, the subject matter of Examples 8-12 includes, wherein the search pattern includes fuzzy logic rules.

In Example 14, the subject matter of Examples 8-13 includes, wherein the search pattern includes a finite state automaton.

Example 15 is an edge computing system, comprising a plurality of edge computing nodes, the plurality of edge computing nodes configured with the biometric security methods of any of Examples 8 to 14 or 86 to 97.

Example 16 is an edge computing node, operable in an edge computing system, comprising processing circuitry configured to implement any of the methods of Examples 8 to 14 or 86 to 97.

Example 17 is an edge computing node, operable as a server in an edge computing system, configured to perform any of the methods of Examples 8 to 14 or 86 to 97.

Example 18 is an edge computing node, operable as a client in an edge computing system, configured to perform any of the methods of Examples 8 to 14 or 86 to 97.

Example 19 is an edge computing node, operable in a layer of an edge computing network as an aggregation node, network hub node, gateway node, or core data processing node, configured to perform any of the methods of Examples 8 to 14 or 86 to 97.

Example 20 is an edge computing network, comprising networking and processing components configured to provide or operate a communications network, to enable an edge computing system to implement any of the methods of Examples 8 to 14 or 86 to 97.

Example 21 is an access point, comprising networking and processing components configured to provide or operate a communications network, to enable an edge computing system to implement any of the methods of Examples 8 to 14 or 86 to 97.

Example 22 is a base station, comprising networking and processing components configured to provide or operate a communications network, to enable an edge computing system to implement any of the methods of Examples 8 to 14 or 86 to 97.

Example 23 is a road-side unit, comprising networking components configured to provide or operate a communications network, to enable an edge computing system to implement any of the methods of Examples 8 to 14 or 86 to 97.

Example 24 is an on-premise server, operable in a private communications network distinct from a public edge computing network, the server configured to enable an edge computing system to implement any of the methods of Examples 8 to 14 or 86 to 97.

Example 25 is a 3GPP 4G/LTE mobile wireless communications system, comprising networking and processing components configured with the biometric security methods of any of Examples 8 to 14 or 86 to 97.

Example 26 is a 5G network mobile wireless communications system, comprising networking and processing components configured with the biometric security methods of any of Examples 8 to 14 or 86 to 97.

Example 27 is a user equipment device, comprising networking and processing circuitry, configured to connect with an edge computing system configured to implement any of the methods of Examples 8 to 14 or 86 to 97.

Example 28 is a client computing device, comprising processing circuitry, configured to coordinate compute operations with an edge computing system, the edge computing system configured to implement any of the methods of Examples 8 to 14 or 86 to 97.

Example 29 is an edge provisioning node, operable in an edge computing system, configured to implement any of the methods of Examples 8 to 14 or 86 to 97.

Example 30 is a service orchestration node, operable in an edge computing system, configured to implement any of the methods of Examples 8 to 14 or 86 to 97.

Example 31 is an application orchestration node, operable in an edge computing system, configured to implement any of the methods of Examples 8 to 14 or 86 to 97.

Example 32 is a multi-tenant management node, operable in an edge computing system, configured to implement any of the methods of Examples 8 to 14 or 86 to 97.

Example 33 is an edge computing system comprising processing circuitry, the edge computing system configured to operate one or more functions and services to implement any of the methods of Examples 8 to 14 or 86 to 97.

Example 34 is networking hardware with network functions implemented thereupon, operable within an edge computing system configured with the biometric security methods of any of Examples 8 to 14 or 34 86 to 97.

Example 35 is acceleration hardware with acceleration functions implemented thereupon, operable in an edge computing system, the acceleration functions configured to implement any of the methods of Examples 8 to 14 or 86 to 97.

Example 36 is storage hardware with storage capabilities implemented thereupon, operable in an edge computing system, the storage hardware configured to implement any of the methods of Examples 8 to 14 or 86 to 97.

Example 37 is computation hardware with compute capabilities implemented thereupon, operable in an edge computing system, the computation hardware configured to implement any of the methods of Examples 8 to 14 or 86 to 97.

Example 38 is an edge computing system adapted for supporting vehicle-to-vehicle (V2V), vehicle-to-everything (V2X), or vehicle-to-infrastructure (V2I) scenarios, configured to implement any of the methods of Examples 8 to 14 or 86 to 97.

Example 39 is an edge computing system adapted for operating according to one or more European Telecommunications Standards Institute (ETSI) Multi-Access Edge Computing (MEC) specifications, the edge computing system configured to implement any of the methods of Examples 8 to 14 or 86 to 97.

Example 40 is an edge computing system adapted for operating one or more multi-access edge computing (MEC) components, the MEC components provided from one or more of: a MEC proxy, a MEC application orchestrator, a MEC application, a MEC platform, or a MEC service, according to an European Telecommunications Standards Institute (ETSI) Multi-Access Edge Computing (MEC) configuration, the MEC components configured to implement any of the methods of Examples 8 to 14 or 86 to 97.

Example 41 is an edge computing system configured as an edge mesh, provided with a microservice cluster, a microservice cluster with sidecars, or linked microservice clusters with sidecars, configured to implement any of the methods of Examples 8 to 14 or 86 to 97.

Example 42 is an edge computing system, comprising circuitry configured to implement one or more isolation environments provided among dedicated hardware, virtual machines, containers, virtual machines on containers, configured to implement any of the methods of Examples 8 to 14 or 86 to 97.

Example 43 is an edge computing server, configured for operation as an enterprise server, roadside server, street cabinet server, or telecommunications server, configured to implement any of the methods of Examples 8 to 14 or 86 to 97.

Example 44 is an edge computing system configured to implement any of the methods of Examples 8 to 14 or 86 to 97 with use cases provided from one or more of: compute offload, data caching, video processing, network function virtualization, radio access network management, augmented reality, virtual reality, autonomous driving, vehicle assistance, vehicle communications, industrial automation, retail services, manufacturing operations, smart buildings, energy management, internet of things operations, object detection, speech recognition, healthcare applications, gaming applications, or accelerated content processing.

Example 45 is an edge computing system, comprising computing nodes operated by multiple owners at different geographic locations, configured to implement any of the methods of Examples 8 to 14 or 86 to 97.

Example 46 is a cloud computing system, comprising data servers operating respective cloud services, the respective cloud services configured to coordinate with an edge computing system to implement any of the methods of Examples 8 to 14 or 86 to 97.

Example 47 is a server, comprising hardware to operate cloudlet, edgelet, or applet services, the services configured to coordinate with an edge computing system to implement any of the methods of Examples 8 to 14 or 86 to 97.

Example 48 is an edge node in an edge computing system, comprising one or more devices with at least one processor and memory to implement any of the methods of Examples 8 to 14 or 86 to 97.

Example 49 is an edge node in an edge computing system, the edge node operating one or more services provided from among: a management console service, a telemetry service, a provisioning service, an application or service orchestration service, a virtual machine service, a container service, a function deployment service, or a compute deployment service, or an acceleration management service, the one or more services configured to implement any of the methods of Examples 8 to 14 or 86 to 97.

Example 50 is a set of distributed edge nodes, distributed among a network layer of an edge computing system, the network layer comprising a close edge, local edge, enterprise edge, on-premise edge, near edge, middle, edge, or far edge network layer, configured to implement any of the methods of Examples 8 to 14 or 86 to 97.

Example 51 is an apparatus of an edge computing system comprising: one or more processors and one or more computer-readable media comprising instructions that, when executed by the one or more processors, cause the one or more processors to perform any of the methods of Examples 8 to 14 or 86 to 97.

Example 52 is one or more computer-readable storage media comprising instructions to cause an electronic device of an edge computing system, upon execution of the instructions by one or more processors of the electronic device, to perform any of the methods of Examples 8 to 14 or 86 to 97.

Example 53 is a communication signal communicated in an edge computing system, to perform any of the methods of Examples 8 to 14 or 86 to 97.

Example 54 is a data structure communicated in an edge computing system, the data structure comprising a datagram, packet, frame, segment, protocol data unit (PDU), or message, to perform any of the methods of Examples 8 to 14 or 86 to 97.

Example 55 is a signal communicated in an edge computing system, the signal encoded with a datagram, packet, frame, segment, protocol data unit (PDU), message, or data to perform any of the methods of Examples 8 to 14 or 86 to 97.

Example 56 is an electromagnetic signal communicated in an edge computing system, the electromagnetic signal carrying computer-readable instructions, wherein execution of the computer-readable instructions by one or more processors causes the one or more processors to perform any of the methods of Examples 8 to 14 or 86 to 97.

Example 57 is a computer program used in an edge computing system, the computer program comprising instructions, wherein execution of the program by a processing element in the edge computing system is to cause the processing element to perform any of the methods of Examples 8 to 14 or 86 to 97.

Example 58 is an apparatus of an edge computing system comprising means to perform any of the methods of Examples 8 to 14 or 86 to 97.

Example 59 is an apparatus of an edge computing system comprising logic, modules, or circuitry to perform any of the methods of Examples 8 to 14 or 86 to 97.

Example 60 is at least one machine-readable medium including instructions for searching time-aware general purpose input/output signals for patterns, which when executed by a machine, cause the machine to perform operations comprising: detecting rising or falling edges in an input signal; storing the rising or falling edges in a buffer along with a corresponding timestamp of the respective edge; analyzing the rising or falling edges in the buffer to identify a pattern of edges that matches a search pattern; and storing timestamps corresponding to the pattern of edges in an event queue, the event queue used to notify a user application of the existence of the pattern of edges in the input signal.

In Example 61, the subject matter of Example 60 includes, wherein the input signal is from an external device.

In Example 62, the subject matter of Examples 60-61 includes, wherein the search pattern is provided by the user application.

In Example 63, the subject matter of Examples 60-62 includes, wherein the search pattern includes a regular expression.

In Example 64, the subject matter of Example 63 includes, wherein the regular expression includes a pattern of rising edges, falling edges, and no-change during clock cycles while the input signal is received.

In Example 65, the subject matter of Examples 60-64 includes, wherein the search pattern includes fuzzy logic rules.

In Example 66, the subject matter of Examples 60-65 includes, wherein the search pattern includes a finite state automaton.

Example 67 is an apparatus for searching time-aware general purpose input/output signals for patterns, comprising: means for detecting rising or falling edges in an input signal; means for storing the rising or falling edges in a buffer along with a corresponding timestamp of the respective edge; means for analyzing the rising or falling edges in the buffer to identify a pattern of edges that matches a search pattern; and means for storing timestamps corresponding to the pattern of edges in an event queue, the event queue used to notify a user application of the existence of the pattern of edges in the input signal.

In Example 68, the subject matter of Example 67 includes, wherein the input signal is from an external device.

In Example 69, the subject matter of Examples 67-68 includes, wherein the search pattern is provided by the user application.

In Example 70, the subject matter of Examples 67-69 includes, wherein the search pattern includes a regular expression.

In Example 71, the subject matter of Example 70 includes, wherein the regular expression includes a pattern of rising edges, falling edges, and no-change during clock cycles while the input signal is received.

In Example 72, the subject matter of Examples 67-71 includes, wherein the search pattern includes fuzzy logic rules.

In Example 73, the subject matter of Examples 67-72 includes, wherein the search pattern includes a finite state automaton.

Example 74 is a system for time-aware general purpose input/output signal compression, comprising: edge detector circuitry to: detect rising or falling edges in an input signal; and determine the corresponding timestamps of the rising or falling edges; store the timestamps corresponding to the rising or falling edges in an event queue as timestamp groups according to a timestamp grouping configuration; and queue manager circuitry to: access a compression specification; determine when the capacity of the event queue exceeds a threshold; and compress the event queue according to the compression specification, the event queue used to notify a user application.

In Example 75, the subject matter of Example 74 includes, wherein to compress the queue, the queue manager circuitry is to drop a timestamp group from the queue.

In Example 76, the subject matter of Example 75 includes, wherein the compression specification includes group priorities to determine which timestamp group to drop from the queue.

In Example 77, the subject matter of Example 76 includes, wherein the group priorities include a number N of timestamp groups to preserve at the head of the queue.

In Example 78, the subject matter of Examples 74-77 includes, wherein to compress the queue, the queue manager circuitry is to drop a timestamp from a timestamp group.

In Example 79, the subject matter of Example 78 includes, wherein the compression specification includes a drop mask to indicate which timestamp to drop from a timestamp group.

In Example 80, the subject matter of Example 79 includes, wherein the drop mask is static drop mask.

In Example 81, the subject matter of Examples 79-80 includes, wherein the drop mask is provided by the user application.

In Example 82, the subject matter of Examples 79-81 includes, wherein the drop mask is a dynamic drop mask.

In Example 83, the subject matter of Example 82 includes, wherein the dynamic drop mask is modified at run time using a machine learning process.

In Example 84, the subject matter of Examples 82-83 includes, wherein the dynamic drop mask is modified at run time using a fuzzy logic process.

In Example 85, the subject matter of Examples 74-84 includes, wherein to compress the queue, the queue manager circuitry is to reduce the size of a timestamp group.

Example 86 is a method for time-aware general purpose input/output signal compression, comprising: detecting rising or falling edges in an input signal; determining the corresponding timestamps of the rising or falling edges; storing the timestamps corresponding to the rising or falling edges in an event queue as timestamp groups according to a timestamp grouping configuration; accessing a compression specification; determining when the capacity of the event queue exceeds a threshold; and compressing the event queue according to the compression specification, the event queue used to notify a user application.

In Example 87, the subject matter of Example 86 includes, wherein compressing the event queue comprises dropping a timestamp group from the queue.

In Example 88, the subject matter of Example 87 includes, wherein the compression specification includes group priorities to determine which timestamp group to drop from the queue.

In Example 89, the subject matter of Example 88 includes, wherein the group priorities include a number N of timestamp groups to preserve at the head of the queue.

In Example 90, the subject matter of Examples 86-89 includes, wherein compressing the event queue comprises dropping a timestamp from a timestamp group.

In Example 91, the subject matter of Example 90 includes, wherein the compression specification includes a drop mask to indicate which timestamp to drop from a timestamp group.

In Example 92, the subject matter of Example 91 includes, wherein the drop mask is static drop mask.

In Example 93, the subject matter of Examples 91-92 includes, wherein the drop mask is provided by the user application.

In Example 94, the subject matter of Examples 91-93 includes, wherein the drop mask is a dynamic drop mask.

In Example 95, the subject matter of Example 94 includes, wherein the dynamic drop mask is modified at run time using a machine learning process.

In Example 96, the subject matter of Examples 94-95 includes, wherein the dynamic drop mask is modified at run time using a fuzzy logic process.

In Example 97, the subject matter of Examples 86-96 includes, wherein compressing the event queue comprises reducing the size of a timestamp group.

Example 98 is at least one machine-readable medium including instructions for time-aware general purpose input/output signal compression, which when executed by a machine, cause the machine to perform operations comprising: detecting rising or falling edges in an input signal; determining the corresponding timestamps of the rising or falling edges; storing the timestamps corresponding to the rising or falling edges in an event queue as timestamp groups according to a timestamp grouping configuration; accessing a compression specification; determining when the capacity of the event queue exceeds a threshold; and compressing the event queue according to the compression specification, the event queue used to notify a user application.

In Example 99, the subject matter of Example 98 includes, wherein compressing the event queue comprises dropping a timestamp group from the queue.

In Example 100, the subject matter of Example 99 includes, wherein the compression specification includes group priorities to determine which timestamp group to drop from the queue.

In Example 101, the subject matter of Example 100 includes, wherein the group priorities include a number N of timestamp groups to preserve at the head of the queue.

In Example 102, the subject matter of Examples 98-101 includes, wherein compressing the event queue comprises dropping a timestamp from a timestamp group.

In Example 103, the subject matter of Example 102 includes, wherein the compression specification includes a drop mask to indicate which timestamp to drop from a timestamp group.

In Example 104, the subject matter of Example 103 includes, wherein the drop mask is static drop mask.

In Example 105, the subject matter of Examples 103-104 includes, wherein the drop mask is provided by the user application.

In Example 106, the subject matter of Examples 103-105 includes, wherein the drop mask is a dynamic drop mask.

In Example 107, the subject matter of Example 106 includes, wherein the dynamic drop mask is modified at run time using a machine learning process.

In Example 108, the subject matter of Examples 106-107 includes, wherein the dynamic drop mask is modified at run time using a fuzzy logic process.

In Example 109, the subject matter of Examples 98-108 includes, wherein compressing the event queue comprises reducing the size of a timestamp group.

Example 110 is an apparatus for time-aware general purpose input/output signal compression, comprising: means for detecting rising or falling edges in an input signal; means for determining the corresponding timestamps of the rising or falling edges; means for storing the timestamps corresponding to the rising or falling edges in an event queue as timestamp groups according to a timestamp grouping configuration; means for accessing a compression specification; means for determining when the capacity of the event queue exceeds a threshold; and means for compressing the event queue according to the compression specification, the event queue used to notify a user application.

In Example 111, the subject matter of Example 110 includes, wherein the means for compressing the event queue comprise means for dropping a timestamp group from the queue.

In Example 112, the subject matter of Example 111 includes, wherein the compression specification includes group priorities to determine which timestamp group to drop from the queue.

In Example 113, the subject matter of Example 112 includes, wherein the group priorities include a number N of timestamp groups to preserve at the head of the queue.

In Example 114, the subject matter of Examples 110-113 includes, wherein the means for compressing the event queue comprise means for dropping a timestamp from a timestamp group.

In Example 115, the subject matter of Example 114 includes, wherein the compression specification includes a drop mask to indicate which timestamp to drop from a timestamp group.

In Example 116, the subject matter of Example 115 includes, wherein the drop mask is static drop mask.

In Example 117, the subject matter of Examples 115-116 includes, wherein the drop mask is provided by the user application.

In Example 118, the subject matter of Examples 115-117 includes, wherein the drop mask is a dynamic drop mask.

In Example 119, the subject matter of Example 118 includes, wherein the dynamic drop mask is modified at run time using a machine learning process.

In Example 120, the subject matter of Examples 118-119 includes, wherein the dynamic drop mask is modified at run time using a fuzzy logic process.

In Example 121, the subject matter of Examples 110-120 includes, wherein the means for compressing the event queue comprise means for reducing the size of a timestamp group.

Example 122 is at least one machine-readable medium including instructions that, when executed by processing circuitry, cause the processing circuitry to perform operations to implement of any of Examples 1-121.

Example 123 is an apparatus comprising means to implement of any of Examples 1-121.

Example 124 is a system to implement of any of Examples 1-121.

Example 125 is a method to implement of any of Examples 1-121.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof), or with respect to other examples (or one or more aspects thereof) shown or described herein.

Publications, patents, and patent documents referred to in this document are incorporated by reference herein in their entirety, as though individually incorporated by reference. In the event of inconsistent usages between this document and those documents so incorporated by reference, the usage in the incorporated reference(s) are supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to suggest a numerical order for their objects.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined with reference to the appended claims, along with the full scope of equivalents to which such claims are entitled.

What is claimed is:

1. A system for searching time-aware general purpose input/output signals for patterns, comprising:
edge detector circuitry to:
detect rising or falling edges in an input signal; and
store the rising or falling edges in a buffer along with a corresponding timestamp of the respective edge; and
pattern match circuitry to:
analyze the rising or falling edges in the buffer to identify a pattern of edges that matches a search pattern; and
store timestamps corresponding to the pattern of edges in an event queue, the event queue used to notify a user application of the existence of the pattern of edges in the input signal.

2. The system of claim 1, wherein the input signal is from an external device.

3. The system of claim 1, wherein the search pattern is provided by the user application.

4. The system of claim 1, wherein the search pattern includes a regular expression.

5. The system of claim 4, wherein the regular expression includes a pattern of rising edges, falling edges, and no-change during clock cycles while the input signal is received.

6. The system of claim 1, wherein the search pattern includes fuzzy logic rules.

7. The system of claim 1, wherein the search pattern includes a finite state automaton.

8. A method for searching time-aware general purpose input/output signals for patterns, comprising:
detecting rising or falling edges in an input signal;
storing the rising or falling edges in a buffer along with a corresponding timestamp of the respective edge;
analyzing the rising or falling edges in the buffer to identify a pattern of edges that matches a search pattern; and
storing timestamps corresponding to the pattern of edges in an event queue, the event queue used to notify a user application of the existence of the pattern of edges in the input signal.

9. The method of claim 8, wherein the input signal is from an external device.

10. The method of claim 8, wherein the search pattern is provided by the user application.

11. The method of claim 8, wherein the search pattern includes a regular expression.

12. The method of claim 11, wherein the regular expression includes a pattern of rising edges, falling edges, and no-change during clock cycles while the input signal is received.

13. The method of claim 8, wherein the search pattern includes fuzzy logic rules.

14. The method of claim 8, wherein the search pattern includes a finite state automaton.

15. A system for time-aware general purpose input/output signal compression, comprising:
edge detector circuitry to:
detect rising or falling edges in an input signal; and
determine the corresponding timestamps of the rising or falling edges;
store the timestamps corresponding to the rising or falling edges in an event queue as timestamp groups according to a timestamp grouping configuration; and
queue manager circuitry to:
access a compression specification;
determine when the capacity of the event queue exceeds a threshold; and
compress the event queue according to the compression specification, the event queue used to notify a user application.

16. The system of claim 15, wherein to compress the queue, the queue manager circuitry is to drop a timestamp group from the queue.

17. The system of claim 16, wherein the compression specification includes group priorities to determine which timestamp group to drop from the queue.

18. The system of claim 17, wherein the group priorities include a number N of timestamp groups to preserve at the head of the queue.

19. The system of claim 15, wherein to compress the queue, the queue manager circuitry is to drop a timestamp from a timestamp group.

20. The system of claim 19, wherein the compression specification includes a drop mask to indicate which timestamp to drop from a timestamp group.

21. The system of claim 20, wherein the drop mask is static drop mask.

22. The system of claim 20, wherein the drop mask is provided by the user application.

23. The system of claim 20, wherein the drop mask is a dynamic drop mask.

24. The system of claim 23, wherein the dynamic drop mask is modified at run time using a machine learning process.

25. The system of claim 23, wherein the dynamic drop mask is modified at run time using a fuzzy logic process.

26. The system of claim 15, wherein to compress the queue, the queue manager circuitry is to reduce the size of a timestamp group.
